(19) United States
(12) Patent Application Publication
(10) Pub. No.: US 2010/0300359 A1
(43) Pub. Date: Dec. 2, 2010

(54) MULTI-GAS DISTRIBUTION INJECTOR FOR CHEMICAL VAPOR DEPOSITION REACTORS

(75) Inventors: Eric A. Armour, Pennington, NJ (US); Alex Gurary, Bridgewater, NJ (US); Lev Kadinski, Burghausen (DE); Robert Doppelhammer, Delano, MN (US); Gary Tompa, Belle Mead, NJ (US); Mikhail Kats, Rockaway, NJ (US)

Correspondence Address: LERNER, DAVID, LITTENBERG,;KRUMHOLZ & MENTLIK, 600 SOUTH AVENUE WEST, WESTFIELD, NJ, 07090, US

(73) Assignee: VEECO INSTRUMENTS INC., Plainview, NY (US)

(21) Appl. No.: 12/857,083

(22) Filed: Aug. 16, 2010

Related U.S. Application Data
(63) Continuation of application No. 11/192,483, filed on Jul. 29, 2005.
(60) Provisional application No. 60/598,172, filed on Aug. 2, 2004.

(51) Int. Cl. C23C 16/458; C23C 16/00

(52) U.S. Cl. 118/724; 118/715; 118/730

(57) ABSTRACT

A gas distribution injector for chemical vapor deposition reactors has precursor gas inlets disposed at spaced-apart locations on an inner surface facing downstream toward a substrate carrier, and has carrier openings disposed between the precursor gas inlets. One or more precursor gases are introduced through the precursor gas inlets, and a carrier gas substantially nonreactive with the precursor gases is introduced through the carrier gas openings. The carrier gas minimizes deposit formation on the injector. The carrier gas openings may be provided by a porous plate defining the surface or via carrier inlets interspersed between precursor inlets. The gas inlets may removable or coaxial.

### CROSS-REFERENCE TO RELATED APPLICATIONS

This application is a continuation of U.S. application Ser. No. 11/192,483, filed on Jul. 29, 2005, which claims the benefit of the filing date of U.S. Provisional Patent Application No. 60/598,172, filed Aug. 2, 2004, the disclosures of which are hereby incorporated herein by reference.

### BACKGROUND OF THE INVENTION

This invention relates to systems for reactive gas phase processing such as chemical vapor deposition, and is more specifically related to the structure of a multi-gas distribution injector for use in such reactors.

Chemical vapor deposition (“CVD”) reactors permit the treatment of wafers mounted on a wafer carrier disposed inside a reaction chamber. A component referred to as a gas distribution injector, such as those sold by the assignee of the present application under the trademark FLOWFLANGE, is mounted facing towards the wafer carrier. The injector typically includes a plurality of gas inlets that provide some combination of one or more precursor gases to the chamber for chemical vapor deposition. Some gas distribution injectors provide a shroud or carrier gases that help provide a laminar gas flow during the chemical vapor deposition process, where the carrier gas typically does not participate in chemical vapor deposition. Many gas distribution injectors have showerhead designs including gas inlets spaced in a pattern on the head.

A gas distribution injector typically permits the direction of precursor gases from gas inlets on an injector surface towards certain targeted regions of the reaction chamber where wafers can be treated for processes such as epitaxial growth of material layers. Ideally, the precursor gases are directed at the wafer carrier in such a way that the precursor gases react as close to the wafers as possible, thus maximizing reaction processes and epitaxial growth at the wafer surface.

In many metal organic chemical vapor deposition (MOCVD) processes, for example, combinations of precursor gases and vapors comprised of film precursors, such as metal organics or metal hydrides or chlorides, are introduced into a reaction chamber through the injector. Process-facilitating carrier gases, such as hydrogen, nitrogen, or inert gases, such as argon or helium, also may be introduced into the reactor through the injector. The precursor gases mix in the reaction chamber and react to form a deposit on a wafer held within the chamber, and the carrier gases typically aid in maintaining laminar flow at the wafer carrier.

In this way, epitaxial growth of semiconductor compounds such as, for example, GaAs, GaN, GaAlAs, InGaAsSb, InP, ZnSe, ZnTe, HgCdTe, InAsSbP, InGaN, AlGaN, SiGe, SiC, ZnO and InGaAlP, and the like, can be achieved.

However, many existing gas injector systems have problems that may interfere with efficient operation or even deposition. For example, precursor injection patterns in existing gas distribution injector systems may contain significant “dead space” (space without active flow from gas inlets on the injector surface) resulting in recirculation patterns near the injector.

These recirculation patterns may result in prereaction of the precursor chemicals, causing unwanted deposition of reactants on the injector inlets (referred to herein as “reverse jetting”). This can also result in lower efficiency and memory effects.

An inlet density of around 100/in² (15.5/cm²) or more is typically used in current systems (resulting in approximately 10,000 inlets for typical large scale production MOCVD systems). Previous attempts to increase the distance between inlets have sometimes led to larger dead zones and increased reverse jetting. However, systems requiring a large number of inlets sometimes occasion difficulties in manufacture and consistency. This greater inlet density may, in some configurations, result in penetration of precursor from one inlet into another, clogging the inlets with parasitic reaction products from interaction of the precursors. Also, an injector design with small distances between inlets may not, in some configurations, allow enough space for the optical viewports required for many types of in-situ characterization devices frequently required in modern MOCVD equipment.

In addition, the difference in decomposition rate for different precursors in the reaction chamber above the carrier and wafer (such as for multi-wafer systems) may not always be amenable to other solutions, such as uniform inlet distribution. Similarly, uniform distribution alone may not always account for small temperature non-uniformities sometimes present at the wafer carrier. These additional problems may, in some systems, result in non-uniform thickness and doping level of the grown epitaxial layers. Problems such as surface migration, evaporation, and gas depletion resulting in uneven distribution can further hinder efficient deposition.

In addition to the structure of the gas distribution injector and its inlets, other factors including temperature, residence times, and other nuances of process chemistry, including catalytic effects and surface reactivity also affect the growth of material layers on wafers placed in a MOCVD reactor.

Moreover, unreacted precursor may contribute to uneven deposition. Consequently, the proportion of byproduct and/or unreacted precursors may be less or greater over different regions of a wafer or different wafers on a multi-wafer carrier, and deposition is less or more efficient in those regions—a result inimical to the goal of uniform material deposition.

Due to reactant buildup, currently available gas distribution injectors frequently must be removed from the rotating disk reactor for cleaning. Frequent injector cleaning may interfere with efficient reactor operation, and may require increased handling and disposal of waste product during the cleaning process. This may result in reduced yield and increased cost.

Thus, despite all of the efforts in this area, further improvement would be desirable.

### SUMMARY OF THE INVENTION

A method of chemical vapor deposition according to one aspect of the invention includes discharging at least one precursor gas as a plurality of streams into a reaction chamber through a plurality of spaced-apart precursor inlets in a gas distribution injector so that the streams have a component of velocity in a downstream direction away from the injector towards one or more substrates disposed in the chamber, the at least one precursor gas reacting to form a reaction deposit on the one or more substrates; and, simultaneously, discharging at least one carrier gas substantially nonreactive with the at least one precursor gases into the chamber from the injector between a plurality of adjacent ones of the precursor inlets. Preferably, the step of discharging the at least one carrier gas may include discharging the carrier gas through a porous structure in the injector extending between adjacent ones of the precursor inlets, or the step of discharging the at least one carrier gas may include discharging the carrier gas through a plurality of spaced apart carrier inlets in the injector disposed between adjacent ones of the precursor inlets.

In one aspect, a gas distribution injector for a chemical vapor deposition reactor is provided including a structure defining an interior surface facing in a downstream direction and having a horizontal extent, a plurality of precursor inlets open to the interior surface at horizontally-spaced precursor inlet locations, one or more precursor gas connections and one or more precursor manifolds connecting the one or more precursor gas connections with the precursor inlets, the structure including a porous element having first and second surfaces, the second surface of the porous element defining at least a portion of the interior surface between at least some of the precursor inlet locations, the structure further defining a carrier gas manifold at least partially bounded by the first surface of the porous element and at least one carrier gas connection communicating with the carrier gas manifold.

In one aspect the injector further includes first precursor inlets open to the interior surface at first precursor inlet locations and second precursor inlets open to the interior surface at second precursor inlet locations, the one or more precursor gas connections including one or more first precursor connections and one or more second precursor connections, the one or more precursor manifolds include one or more first precursor manifolds connecting the one or more first precursor connections with the first precursor inlets and one or more second precursor manifolds connecting the second precursor connections with the second precursor inlets, at least some of the first and second precursor inlet locations being interspersed with one another over at least part of the horizontal extent of the interior surface, the porous element extending between at least some of the first and second precursor inlet locations.

In one aspect the injector further includes one or more coolant passages, the coolant passage bounded by coolant passage walls defining a serpentine path for the coolant passage there through, the coolant passage not in fluid communication with the precursor inlets or the carrier gas manifold, the precursor inlets extending through the coolant passage walls, and the coolant passage coupled to a coolant entry port and a coolant exhaust port for communication of a coolant there through.

In one aspect the injector still further includes where the first precursor inlets are disposed in a plurality of concentric zones on the interior surface, the one or more first precursor gas connections include a plurality of first precursor connections, the one or more first precursor manifolds including a plurality of first precursor manifolds each said first precursor manifold being connected to the first precursor inlets in one of said zones.

In another aspect, an injector for a chemical vapor deposition reactor includes structure defining an inner surface facing in a downstream direction and extending in horizontal directions transverse to the downstream direction, the structure further defining a plurality of concentric stream inlets opening through the inner surface at horizontally-spaced stream locations, each the concentric stream inlet including a first gas channel open to the inner surface at a first port and a second gas channel open to the inner surface at a second port substantially surrounding the first port, the structure further including at least one first gas manifold connected to the first gas channels, at least one second gas manifold connected to the second gas channels.

In another aspect, the injector further includes a carrier gas manifold at least partially bounded by the inner surface and including a porous screen on the inner surface in the regions of the inner surface between the plurality of concentric stream inlets, the carrier gas manifold connected to the porous screen, or in one aspect, the injector further includes a third gas manifold, each of the concentric stream inlet including a third gas channel open to the inner surface at a third port substantially surrounding the first port, the structure further including a third gas manifold connected to the third gas channels, wherein at least one of the first, second and third gas inlets is a carrier gas inlet and at least one of a the first, second and third gas manifolds is a carrier gas manifold.

The present invention has industrial application to chemical vapor deposition reactors such as rotating disk reactors, but can be applied to other industrial chemical deposition and cleaning apparatuses such as, for example, etching.

### BRIEF DESCRIPTION OF THE DRAWINGS

FIG. 1 is a simplified cross-sectional view of a reactor including a gas distribution injector according to one embodiment of the present invention.

FIG. 2 is a cross-sectional view of one embodiment of a gas distribution injector of the present invention.

FIG. 3 is a magnified cross-section of the gas distribution injector embodiment of FIG. 2.

FIG. 4 is a further cross-sectional view of the injector of FIGS. 2 and 3 according to the present invention incorporating an optical viewport.

FIG. 5 is a fragmentary plan view of the gas distribution injector of FIGS. 2-4 viewed from below within a reactor.

FIG. 6 is a simplified cross-section view of a gas distribution injector according to the present invention.

FIG. 7 is a diagrammatic view of yet another embodiment of a gas distribution injector of the present invention viewed from below demonstrating a “mosaic” pattern of precursor inlets and carrier inlets.

FIG. 8A is a diagrammatic view of a further embodiment of a gas distribution injector of the present invention viewed from below demonstrating a pattern of first and second precursor inlets and a carrier plate.

FIG. 8B is a diagrammatic view of a still further embodiment of a gas distribution injector of the present invention viewed from below demonstrating a “checkerboard” pattern of first precursor inlets, second precursor inlets, and a carrier screen.

FIG. 9 is a diagrammatic view of yet another embodiment of a gas distribution injector of the present invention viewed from below demonstrating a “mosaic” pattern of first precursor inlets, second precursor inlets, and carrier inlets, with a central optical viewport.

FIG. 10 is a plan view of an embodiment of a gas distribution injector of the present invention viewed from below demonstrating zone-varying concentrations of precursor gases and carrier gases.

FIG. 11 is a perspective view of another embodiment of a gas distribution injector of the present invention viewed from below including zone-varying concentrations of precursor gases and carrier gases.

FIG. 12 is a sectional perspective view of the gas distribution injector of FIG. 11.

FIG. 13 is a magnified portion of the view of FIG. 12.

FIG. 14 is a sectional perspective view of a zoned bottom plate used with the gas distribution injector of FIGS. 11-13.

FIG. 15 is a sectional perspective view of a zoned middle plate used with the gas distribution injector of FIGS. 11-14.

FIG. 16 is a plan view of one embodiment of a zoned top plate of the gas distribution injector of FIGS. 11-15.

FIG. 17 is a close up of one embodiment of the coaxial precursor inlets for use with the gas distribution injector of FIG. 16.

FIG. 18 is a diagrammatic view of one embodiment of a gas distribution injector of the present invention viewed from below demonstrating a zoned “checkerboard” pattern of first precursor inlets, second precursor inlets, and carrier inlets, in three zones of varying concentrations.

FIG. 19 is a diagrammatic view of one embodiment of a gas distribution injector of the present invention viewed from below demonstrating a zoned dual lumen “checkerboard” pattern of dual lumen or coaxial first and second precursor inlets and carrier inlets in three zones of varying concentrations.

FIG. 20 is a close up of one embodiment of dual lumen precursor inlets for use with the gas distribution injector of FIG. 19.

FIGS. 21A-G are cross sectional views of some embodiments of inlets for use with a gas distribution injector of the present invention.

FIG. 22 is a simplified plan view of another embodiment of a gas distribution injector of the present invention including vent screws used for communication of gasses to the reaction chamber.

FIG. 23 is an exploded view of another embodiment of a gas distribution injector of the present invention employing multiple gas distribution plates and including vent screws used for communication of gasses to the reaction chamber.

FIG. 24A is a perspective view of the upstream plate of the embodiment of the gas distribution injector shown in FIG. 22.

FIG. 24B is a downstream (bottom) view of the upstream plate of the embodiment of the gas distribution injector shown in FIG. 22.

FIG. 25 is a perspective view of the middle plate of the embodiment of the gas distribution injector shown in FIG. 22.

FIG. 26A is a perspective view of the middle plate of the embodiment of the gas distribution injector shown in FIG. 22, prior to welding of a cooling chamber closing piece on the upstream surface thereon.

FIG. 26B is a perspective view of the middle plate of the embodiment of the gas distribution injector shown in FIG. 22, after welding of a cooling chamber closing piece on the upstream surface thereon.

FIG. 27 is a downstream view of the downstream plate of the embodiment of the gas distribution injector shown in FIG. 22.

FIG. 28 is a cross-sectional view of one embodiment of a gas distribution injector of the present invention including a porous material placed within the reactant gas inlet passages to create a pressure differential.

FIG. 29 is a cross sectional view of the inner gas distribution surface of one embodiment of a gas distribution injector of the present invention employing a coaxial reactant gas inlet and vent screw.

FIG. 30 is a cross sectional view of the inner gas distribution surface of one embodiment of a gas distribution injector of the present invention employing a dual lumen reactant gas inlet and vent screw and a supplemental reactant gas inlet.

FIG. 31 is a perspective view of a vent screw to be used in one embodiment of the gas distribution injector of the present invention.

FIG. 32 is a perspective view of a coaxial vent screw to be used in one embodiment of the gas distribution injector of the present invention employing coaxial distribution of reactant gases.

### DETAILED DESCRIPTION

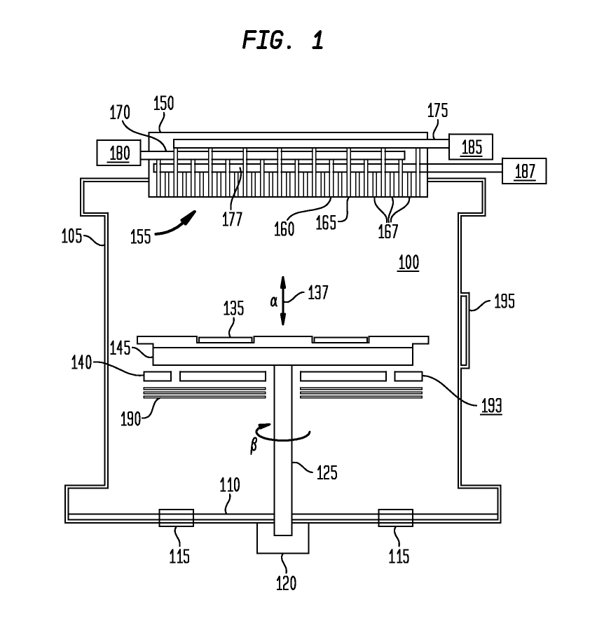

Referring now to the drawings wherein like numerals indicate like elements, FIG. 1 shows a rotating disk reactor incorporating a multi-gas injector according to one embodiment of the present invention.

As diagrammatically shown in FIG. 1, the apparatus includes a cylindrical reaction chamber 100 made of stainless steel walls 105, a base plate 110, exhaust ports 115, and a rotating vacuum feedthrough 120 that seals rotating spindle 125, on top of which is installed a wafer carrier 130 with substrate wafers 135. The wafer carrier is rotatable about an axis 137 (α), coaxial with cylindrical chamber 100, at a predetermined rotation rate (β).

A heating susceptor 145 is heated by a set of heating elements 140, typically made from a refractive metal such as but not limited to, for example, molybdenum, tungsten or rhenium and the like, or a non-metal such as graphite, which may be divided into multiple heating zones. The metal for heating elements may be selected based on the reaction to be performed and heating characteristics required for a particular reactor and chemical vapor deposition chamber. A heat shield 190 is advantageously disposed below the heating elements 140 and susceptor 145. Alternatively, a wafer carrier 130 may be directly heated by radiant heating element 140.

The heating elements 140 and reactor 100 are generally controlled via an external automatic or manual controller 193, and an optional access port 195 advantageously serves to permit access to the wafers 135 and wafer carrier 130 for placement in the reactor 100, optionally from a secondary chamber (not shown). The foregoing components of the reactor may be, for example, of the types used in reactors sold under the trademark TURBODISC® by Veeco Instruments Inc. Although an access port 195 is shown herein, other reactors may have other access systems, such as, for example, top-loading or bottom loading of wafers through a removable top or bottom portion of the reactor.

A gas distribution injector head 150 is located at the upstream end of the chamber 100 (the end toward the top of the drawing as seen in FIG. 1). The gas distribution injector head 150 includes structure which defines an inner surface 155 facing in the downstream direction (the direction along axis 137, toward the bottom of the drawing as seen in FIG. 1) and includes a plurality of first gas inlets 160 connected to a first precursor gas chamber or manifold 170.

Each first gas inlet 160 includes a passageway terminating in a port at the downstream end of the passageway open to the inner surface 155 of the injector. That is, each first gas passageway communicates with the inner surface 155 and with the interior of chamber 100 at a first precursor inlet location. The injector structure further defines a plurality of second gas inlets 165 connected to a second precursor gas chamber or manifold 175. Each second gas inlet also includes a passageway terminating in a port at the downstream end of the passageway open to the inner surface 155 of the injector, so that the second gas inlets 165 also communicate with the interior of chamber 100 at second precursor inlet locations. The first precursor manifold 170 is connected to a source 180 of a first precursor gas, whereas second precursor manifold 175 is connected to a source 185 of a second precursor gas reactive with the first precursor gas.

The first and second precursor inlet locations (the downstream ends of inlets 160 and 165) are spaced apart from one another in horizontal directions (the directions along the inner surface 155, transverse to the downstream direction and transverse to axis 137) so as to form an array of such locations extending over the inner surface of the injector. The first and second precursor locations are interspersed with one another. As further described below, the inlet locations may be disposed in a generally circular array, incorporating several rings of such locations 160, 165 concentric with axis 137, may be randomly placed over the inner surface 155, or may be placed in a checkerboard, mosaic, or another pattern thereon.

The injector structure also incorporates a porous element 167 defining portions of the inner surface 155 between first and second precursor inlet locations. Stated another way, the porous element extends between each first precursor inlet location 160 and the nearest second precursor inlet location 165. The structure further includes a carrier gas manifold schematically indicated at 177 communicating with the porous element 167. The carrier gas manifold is connected to a source 187 of a carrier gas which, under the conditions prevailing within chamber 100, preferably is substantially non-reactive with the first and second precursor gases supplied by sources 180 and 185. As used in this disclosure, the term “substantially non-reactive” means that the carrier gas will not react to any appreciable extent with one or both of the precursor gases in such a way as to form a solid deposit of parasitic adducts. Furthermore, parasitic, gas-phase adducts can also be formed that may be non-reactive and will not deposit, but may still reduce the efficiency of the desired deposition process, and are preferably avoided, although the carrier gas may react appreciably in other ways with the precursor gases. The gases leaving the injector are released downstream from the injector towards a wafer carrier within the reaction chamber. While the present embodiment is shown with a wafer carrier for holding substrates for deposition processes, it is envisioned that a wafer carrier is not necessary and a substrate may be placed directly on a rotating reactor surface such as a chuck, without a wafer carrier holding the substrate. The downstream direction as referred to herein is the direction from the injector toward the wafer carrier; it need not be in any particular orientation relative to gravity. Although the embodiment shown herein shows the downstream direction as being from the top of the chamber towards the bottom of the chamber, the injector may also be placed on the side of the chamber (such that the downstream direction is the direction from the side of the chamber horizontally towards the center of the chamber), or the injector may also be placed on the bottom of the chamber (such that the downstream direction is the direction from the bottom of the chamber upwards towards the center of the chamber). Also, although the exhaust ports 115 are shown at the bottom of the reaction chamber, the exhaust ports may be located on other portions of the reaction chamber.

In operation, one or more wafers 135 are held in the wafer carrier 130 directly above the susceptor 145. The wafer carrier 130 rotates about axis 137 at a rate β on the rotating spindle 125 driven by motor 120. For example, β typically is about 500 RPM or higher, although the rate β may vary. In other embodiments the wafer carrier does not rotate, and, for example, the injector may rotate instead. Electrical power is converted to heat in heating elements 140 and transferred to susceptor 145, principally by radiant heat transfer. The susceptor 145 in turn heats the wafer carrier 130 and wafers 135.

When the wafers are at the desired temperature for the deposition reaction, first precursor source 180 is actuated to feed a first precursor gas through first manifold 170 and first precursor inlets 160, and thereby discharge streams of a first carrier gas generally downstream within chamber 100 from the first precursor inlets. At the same time, the second precursor source 185 is actuated to feed a second precursor gas through manifold 175 and second precursor inlets 165, and thereby discharge streams of the second precursor gas generally downstream, toward the substrates or wafers 130 from the second precursor inlets. The streams of first and second precursors need not be directed exactly downstream, exactly parallel with axis 137. Simultaneously with the supply of precursor gases, the carrier gas supply 187 passes carrier gas through manifold 177, so that the carrier gas passes through the porous element 167 and thus flows generally downstream, away from inner surface 155.

The carrier gas and the first and second precursor gases pass downstream to substrates or wafers 135. During such passage, the gases mix with one another so that the precursor gases react at and near the substrates to form a reaction product that deposits on the exposed surfaces of the substrates.

In the embodiment discussed above, the two precursor gases are provided simultaneously. However, in other embodiments, the precursor gases are supplied sequentially and/or with overlapping pulses. For example, in atomic layer epitaxy, pulses of the precursor gases are applied in alternating sequence, so that a pulse of one carrier gas terminates before a pulse of another gas begins. In a process referred to as migration-enhanced epitaxy, pulses of the different carrier gases are supplied in alternating sequence but overlap one another in time. In a process using sequential precursor gas flows, carrier gas flow may be supplied simultaneously with one or more of the precursor gases.

The carrier gas inhibits deposition of reaction products on the injector. Although the present invention is not limited by any theory of operation, it is believed that the carrier gas flow inhibits reverse or upstream flow of the precursor gases in the immediate vicinity of the inner surface 155. Moreover, it is believed that the carrier gas flow reduces mixing of the first and second precursor gases in the vicinity of the inner surface and thus inhibits formation of reaction products in the vicinity of the injector.

The precursor gases may be any precursor gases suitable for use in a chemical vapor deposition process. Precursor gases in various embodiments may include any gas, vapor, or material which participates in the treatment of a substrate within the reactor. More particularly, the precursor gas may be any gas that is suitable for treating the substrate surface. For example, where the desired deposition is growth of a semiconductor layer such as in epitaxial layer growth, the precursor gas may be a mixture of plural chemical species, and may include inert, non-precursor gas components. Either or both of the precursor gases may include a combination of gases, such as a reactive precursor component and a non-reactive gas. The types of material systems to which the rotating disk reactors of the present invention can be applied can include, for example, Group III-V semiconductors such as but not limited to GaAs, GaP, GaAs₁₋ₓ Pₓ, Ga_{1-y} Al_{y}As, Ga_{1-y}In_{y}As, AlAs, AlN, InAs, InP, InGaP, InSb, GaN, InGaN, and the like. Moreover, these reactors can also be applied to other systems, including Group II-VI compounds, such as but not limited to ZnSe, CdTe, HgCdTe, CdZnTe, CdSeTe, and the like; Group IV-IV compounds, such as SiC, diamond, and SiGe; as well as oxides, such as YBCO, BaTiO, MgO₂, ZrO, SiO₂, ZnO and ZnSiO; and metals, such as Al, Cu and W. Furthermore, the resultant materials will have a wide range of electronic and opto-electronic applications, including but not limited to light emitting diodes (LED's), lasers, solar cells, photocathodes, HEMT's and MESFET's.

The carrier gas may be any carrier desired which does not participate in the deposition reaction in the chamber given the precursor gases to be applied to the substrate, such as an inert gas or a non-participating gas in the reaction.

Although the reactor of FIG. 1 is shown as a vertical rotating disk reactor, this reactor is only provided for example and it is understood that the present invention can be used with other types of reactors such as non-rotating disk reactors, lateral flow reactors, rotating injector reactors, and the like. Additionally, additional precursor gases may be supplied to the chamber via one or more supplementary gas sources, gas chambers and gas inlets. The patterns and structures described herein can thus be readily extended to three, four or more precursors along with one or more carrier gases.

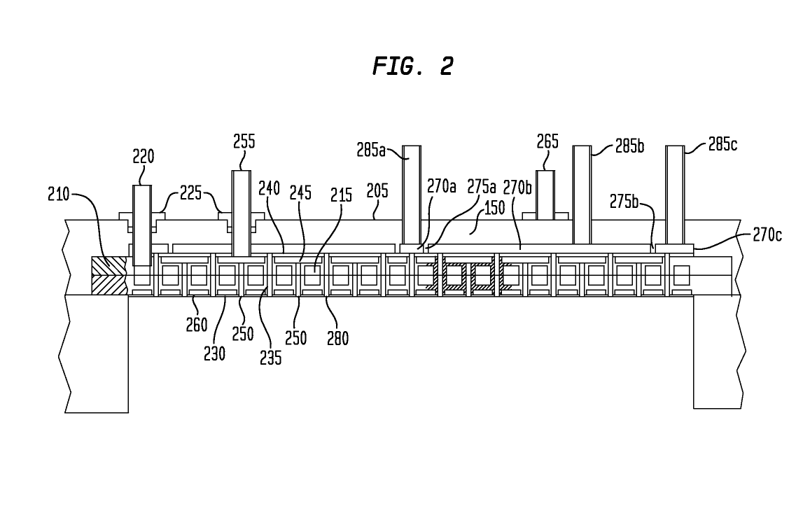

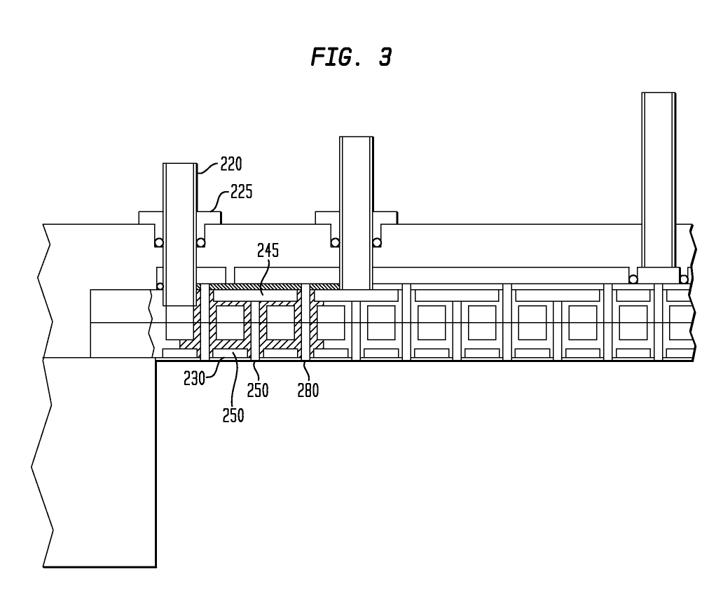

The mechanical construction of injector head 150 and associated elements is depicted in FIGS. 2 and 3. The injector head 150 as seen in FIGS. 2-4 is shown seated in a reactor, such that the downstream surface of the injector (from which gas is injected into the reaction chamber), sometimes referred to as the “bottom” surface, is facing down, and the upstream surface of the injector (from which gas sources supply gas to the injector), sometimes referred to as the “top” surface, is facing up.

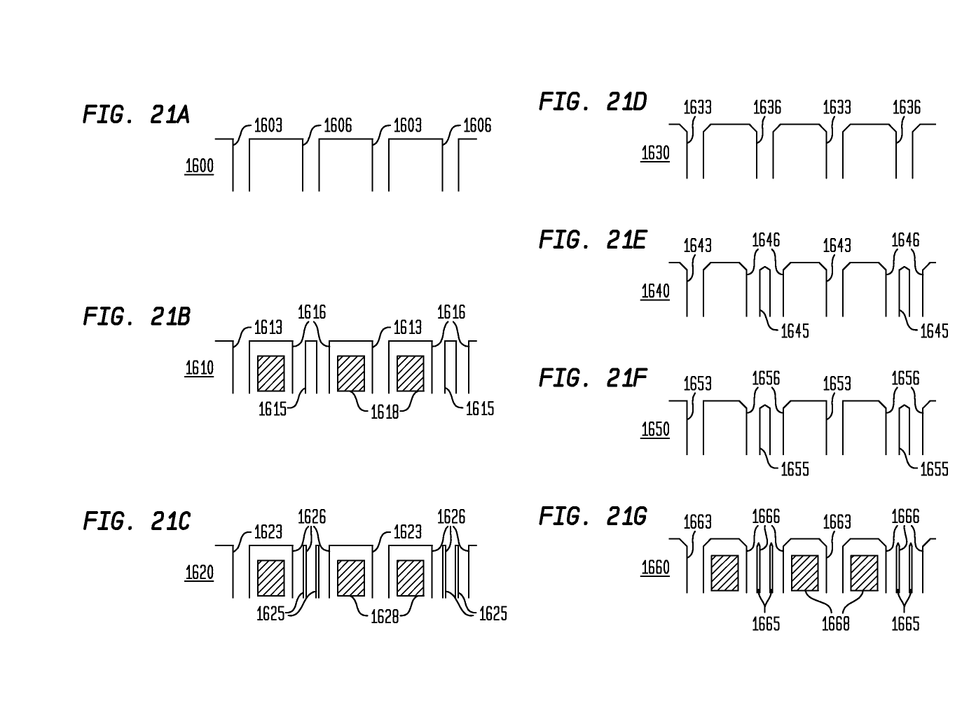

The injector head 150 includes a sealing plate and a gas distribution plate 210, where the gas distribution plate 210 is inserted into an undercut in sealing plate 205 and is connected to the sealing plate 205 by, for example, a number of screws (not shown). The sealing plate advantageously seals the reactor 100 while holding the injector head 150 to the reactor 100. The gas distribution plate 210 has cooling channels 215 for water cooling (see FIGS. 5, 21C) that follow a path around the gas distribution plate 210, and that described in more detail below.

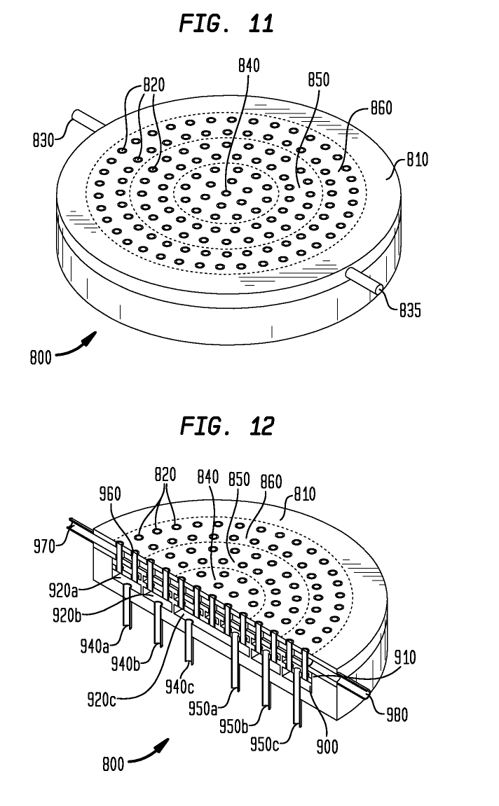

Cooling water is preferably provided through inlet 220 welded to the sealing plate 205 and sealed by an O-ring type seal 225. Similar or other designs (see, for example, FIGS. 12, 16) may be used for the cooling water outflow.

The gas distribution plate 210 is preferably a combination of three elements connected to each other by means of vacuum tight connection (such as, for example, vacuum brazing, diffusion welding, a bolt-and-seal arrangement, and the like). In particular, the gas distribution plate 210 typically comprises an upstream plate 240, a middle plate 235, and a downstream plate 230, one zoned embodiment of which can be seen below in FIGS. 14-17.

The middle plate element 235 forms a first gas chamber 245 and precursor inlets 250. The middle plate element 235 also preferably has water channels 215 for cooling. The first gas chamber 245 is enclosed by upstream plate 240 connected to middle plate 235 by means of a vacuum tight connection.

Precursors are provided to the first gas chamber 245 through a tube 255 welded to the upstream plate 240 and sealed by an O-ring seal 225. These precursors reach the internal reactor space through conduits (inlets) 250.

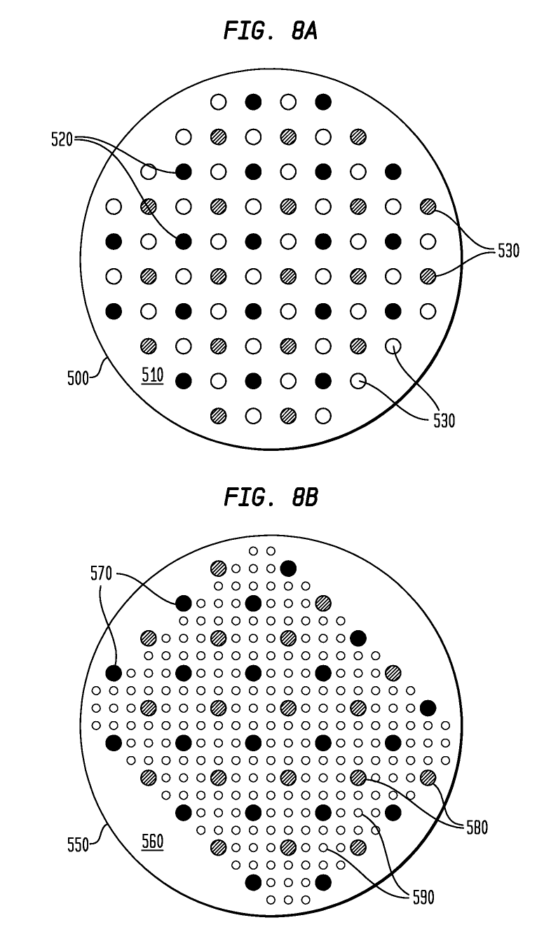

A carrier chamber 260 is connected to the middle element 235 by means of a vacuum tight connection. The carrier chamber 260 is enclosed below by a porous downstream plate 230. Carrier gases are supplied to the carrier chamber 260 through a sealed carrier inlet tube 265 similar to shown in position 255. The porous downstream plate 230 includes small apertures on the surface (i.e. a screen) releasing carrier gas (see, for example, FIG. 8B). Carrier gases reach the internal reactor space through the porous downstream plate 230. Alternatively, a cover plate (not shown) may be placed over the downstream plate as well, as shown in FIGS. 12-16.

A second set of precursor gases are provided to the gas distribution injector in three separate zones. Specifically, zoned precursor chambers 270a-c are formed by the upstream plate 240, circular connectors 275a-b with O-ring seals, and the sealing plate 205. The zoned precursor chambers 270a-c are used to supply precursor reactants into the reactor through precursor conduits 280, where each precursor chamber 270a-c can be separately controlled as to flow rate. Circular connectors 275a-b and three precursor inlet tubes 285a-c provide for three independently controlled zones of precursor inlets, as further elucidated in the embodiments of FIGS. 12-16 below.

A carrier screen in the porous downstream plate 230, precursor inlets 250, and/or zoned precursor inlets or conduits 280, may be uniformly distributed over the inner (downstream) surface of the injector, may be arranged in a non-uniform manner to vary radially in density, or, or as described below, may be uniformly distributed but supplied with precursors and carriers in concentrations varying radially.

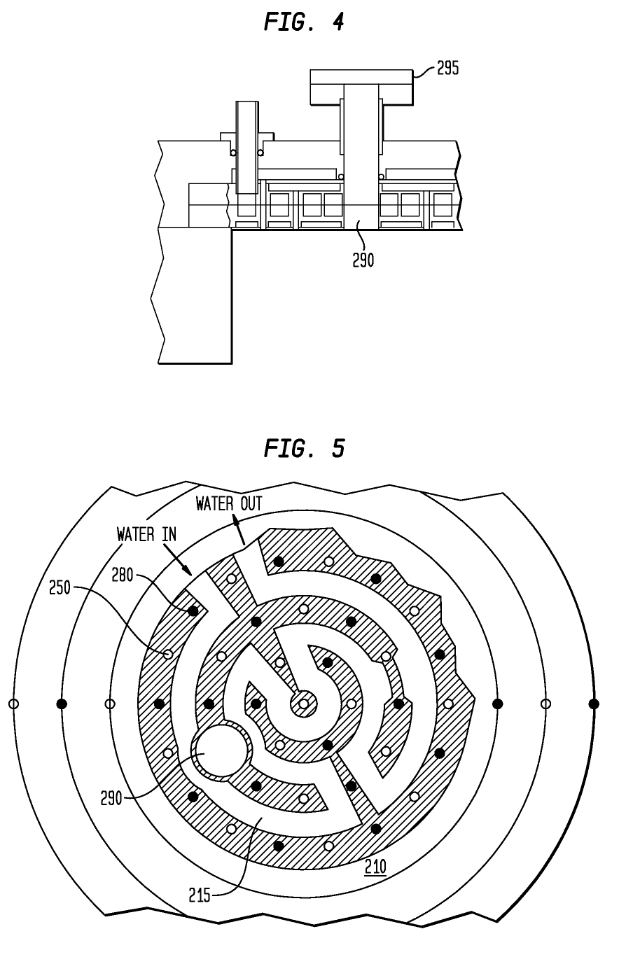

As best seen in FIG. 4, an in-situ optical device 295 opening is provided by hole 290 substituted in place of the one of precursor conduits.

As best seen in FIG. 5, zoned precursor inlets 280 are interspersed with precursor inlets 250 in an alternating pattern along the bottom (downstream) surface of the gas distribution plate 210. A coolant such as, for example, water, glycol, or the like enters, passes through, and exits the injector via serpentine (sinuous) water channels 215. Hole 290 for an optical viewport (not shown) is also provided. In this way constant concentration of the precursors over the wafer carrier 130 (not shown) surface required for the uniform deposition is provided.

### I. Interspersing Multiple Precursor Inlet Patterns With a Carrier Inlet Pattern

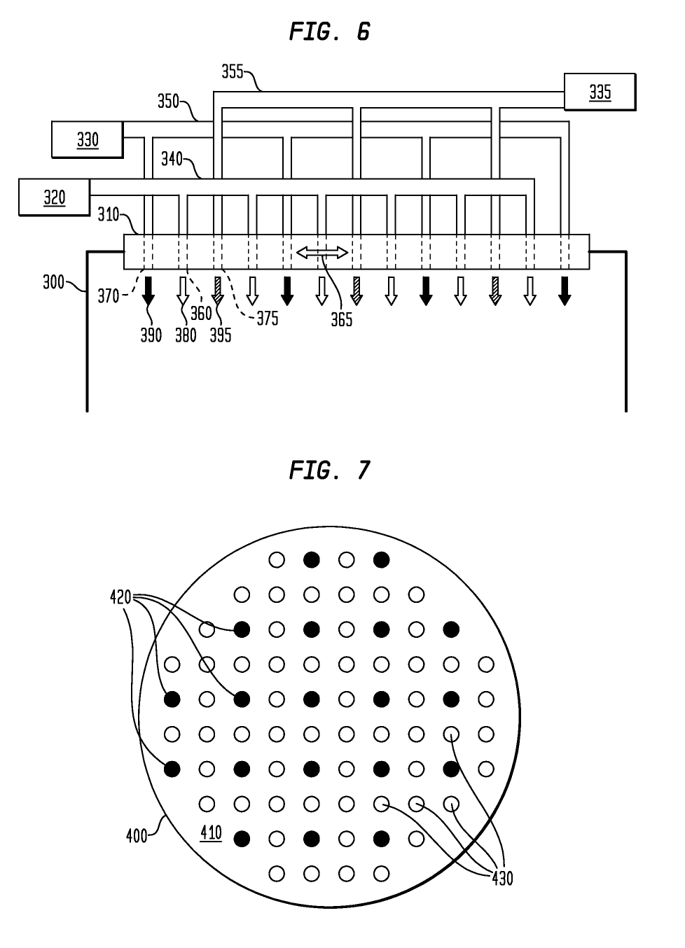

FIG. 6 shows a sectional view of one embodiment of a gas distribution injector of the present invention, where the carrier gas is provided through a third set of inlets rather than a porous plate. It should be understood that although the present embodiment of the subject gas distribution injector is included in a CVD rotating disk reactor, the subject injector is usable with any number of other environments, including different chemical vapor deposition reactors, industrial cleaning environments, and the like.

The upstream end of a rotating disk reactor 300 includes a gas distribution injector 310, again shown in simplified form in radial cross section. A first precursor gas source 330 provides a first precursor gas, through pipe, manifold and valve network 350, at a controllable flow rate to a set of first precursor inlets 370 on the downstream surface of the injector. A precursor gas 390 is distributed into the reactor 300 for, in this instance, CVD treatment of a wafer.

A second precursor gas source 335 provides a second precursor gas 395 through a second pipe, manifold and valve network 355 to a set of second precursor inlets 375. The second precursor gas 395 is also distributed into the reactor on the downstream surface of the injector.

To prevent reverse jetting of precursors back onto or back into the inlets of the injector, the space 365 between precursor inlets on the downstream surface of the injector 310 in this embodiment includes a set of discrete carrier inlets 360. A carrier gas source 320 supplies, via a pipe, manifold and valve network 340, a carrier gas 380 through a second set of inlets 360. The carrier gas 380 is distributed into the reactor 300 at a flow rate set manually via valves (not shown), via control of the carrier gas source 320, or via control of the pipe, manifold and valve network 340.

By providing carrier gas inlets 360, either uniformly or with varying radial density, in spaces 365 between precursor gas inlets 370 and 375 throughout the interior downstream surface of the injector 310, carrier gas flows 380 are thus provided between the first precursor gas streams 390 from each first inlet and the nearest second precursor gas streams 395 from the adjacent second inlets. Here again the carrier gas flows 380 inhibit mixing of the first precursor gas stream 390 and second precursor gas stream 395 in the immediate vicinity of the injector interior (downstream) surface. As such, the carrier gas flows 380 aid in minimizing reverse jetting, and buildup of precursor materials on the injector surface and within injector inlets is reduced.

FIG. 7 shows a diagrammatic plan view of a gas distribution injector of one embodiment of the present invention, viewed from the downstream surface (from within a reactor). The injector 400 provides a “mosaic” inlet pattern. The injector 400 includes a downstream (bottom) surface 410, on which precursor inlets 420 and carrier inlets 430 are located. In this embodiment, each precursor inlet is surrounded on all sides by a non-precursor inlet, creating a “mosaic” tile pattern wherein each precursor inlet is completely surrounded by carrier inlets or porous carrier screen. In such a manner, the space between precursor inlets is provided with non-precursor/carrier inlets, such that reverse jetting (and resultant residue precursor buildup) is prevented at the injector. Although FIG. 7 shows only one precursor, it is understood that any number of precursors may be employed in a pattern amongst the precursor inlets. Stated another way, some of precursor inlets 420 may be first inlets for a first precursor gas, whereas others of the precursor inlets 420 may be second precursor inlets for a second precursor gas. Similarly, although FIG. 7 shows carrier inlets, it is understood that carrier gases may also be injected into the reaction chamber via a porous plate including a screen as provided for in FIG. 2.

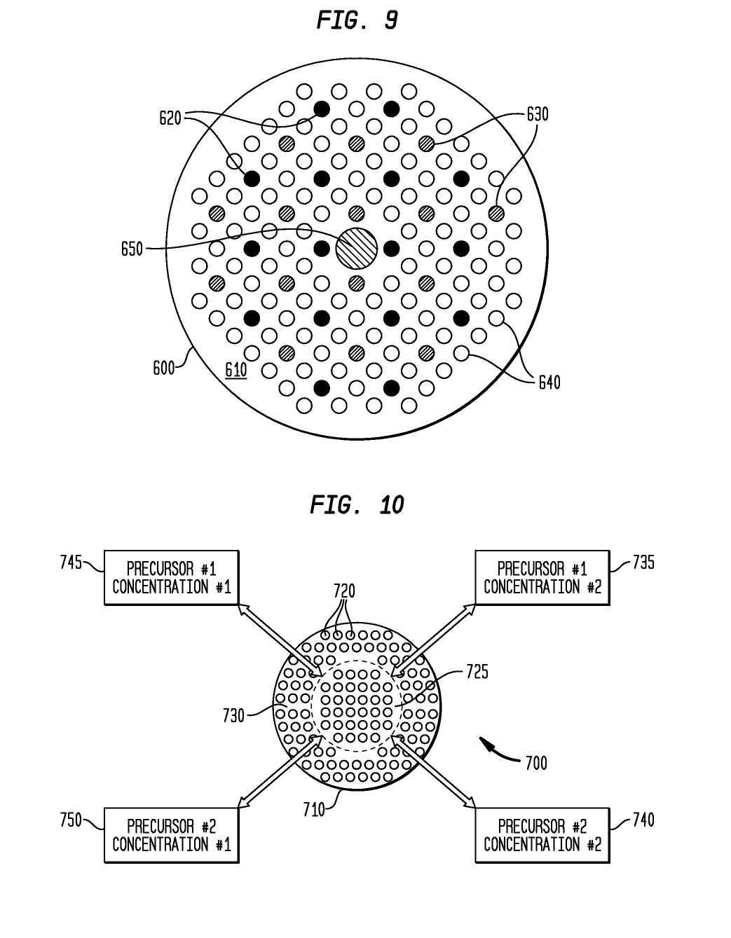

FIGS. 8A, 8B and 9 show example diagrammatic views of gas distribution injectors of various embodiments of the present invention, viewed from the downstream side from within a reactor, employing various combinations of precursor inlets and carrier openings in various configurations on the injector.

In FIG. 8A, a gas distribution injector 500 includes a downstream (bottom) injector surface 510, first precursor inlets 520 in a first pattern, second precursor inlets 530 in a second pattern, and carrier inlets 540. The first precursor and second precursor inlets are interspersed with the carrier inlets in a checkerboard pattern in order to minimize interaction between the first and second reactive gases near the injector itself, thus reducing reverse jetting and precursor product buildup on the injector itself.

FIG. 8B shows an injector 550 with a mosaic pattern of first precursor inlets 570 and second precursor inlets 580 on the injector body 560. Interspersed in the spaces between the multiple precursor inlets are porous screen openings in a porous plate 590 that inject carrier gas into the reaction chamber in the space between precursor inlets, as discussed above with reference to FIGS. 1-4.

Similarly, FIG. 9 shows another embodiment where a gas distribution injector 600 includes an injector interior downstream (bottom) surface 610, first precursor inlets 620 in a first pattern, second precursor inlets 630 in a second pattern, and carrier inlets 640. A central aperture 650 includes a hole for an optical viewport device 295 or for pass-through of other gases or materials used by the reactor. The first precursor and second precursor inlets are interspersed in a mosaic pattern with the carrier inlets in order to minimize interaction between the first and second reactive gases near the injector itself, thus reducing reverse jetting and precursor product buildup on the injector.

The center region of the injector, around the central aperture 650, may have a different arrangement of inlets than the rest of the flange, in order to compensate for the central axis of a rotating disk reactor or a central carrier gas inlet. In this arrangement, carrier gas flows are not provided between those first and second precursor gas inlets that are immediately adjacent to the aperture 650. In other embodiments (not shown), the carrier gas flows may be omitted in other regions, so that carrier gas flows are provided between only some, and not all, pairs of adjacent first and second precursor inlets.

In the embodiments discussed above, spaces between the first and second precursor inlets are purged by carrier flow gas. As a result, pre-reaction between precursors and clogging of the precursor inlets is advantageously reduced.

In addition, the precursor gas inlets may be separated from each other by significant distances. Merely by way of example, the precursor gas inlets may be provided at an inlet density on the order of 10 inlets/in² (1.55 inlets/cm²). It is not necessary to pack the precursor inlets closely in order to minimize reverse jetting. Thus, these embodiments provide for a more reliable and manufactureable design, and provides space for the in-situ optical viewport or other gas pass-throughs. Other distances between inlets may be used, however.

The gas inlets may be placed concentrically, or radially, relative to the central axis of the injector. The concentration of precursors relative to carrier gases may be varied radially. Alternatively or additionally, the density of precursor and carrier inlets on the surface of the injector may vary radially.

### II. Concentration Zoning of Interspersed Carrier/Precursor Inlets

Multizone injection for precursors is, in one embodiment, provided to compensate for effects such as non-uniform precursor decomposition and non-uniform wafer carrier temperature. Preferably, three radial zones are provided, but other configurations are within the scope of the present invention.

Uniform material deposition may be promoted by injecting precursor gases into a reaction chamber at varied concentration levels at various points of injection. Stated another way, precursor concentration may be made a function of the coordinate of precursor injection. Thus, regions of the reaction chamber that would otherwise possess a higher or lower precursor concentration may be “enriched” with lower or higher precursor concentrations in compensation.

One manner in which the above-stated scheme may be implemented is to divide the gas distribution injector into concentric zones. Each concentric zone contains a plurality of inlets, which inject precursor gases into a reaction chamber. The concentration of the precursor gas within each zone is controlled independently by, for example, controlling precursor concentration from radial zone to radial zone. Alternatively, a functionally controlled material deposit having a known non-uniform pattern may be promoted by virtue of controlling precursor concentration from zone to zone. In an alternative embodiment, the concentration of precursor inlets relative to carrier inlets may be varied, or the concentration of precursor inlets overall may be varied, to achieve the same effect.

FIG. 10 depicts a spatially distributed injection system 700, in accordance with an embodiment of the present invention. As can be seen from FIG. 10, the downstream (bottom) surface 710 of an injector 700 defines a plurality of inlets 720. The surface 710 is organized into two zones 725 and 730. In the particular embodiment depicted in FIG. 10, the surface 710 is circular and the zones 725 and 730 are concentric circles. In principle, the surface 710 may be any shape, and need not be planar (it may be spherical, hemispherical, concave, or convex, for example). Similarly, the zones 725 and 730 may be of any shape, and need not be either circular or concentric.

The inlets 720 of each zone 725 and 730 are supplied with two precursor gases originating from separate reservoirs: the inlets in zone 725 are supplied with precursor gases from reservoirs 735 and 740; the inlets in zone 730 are supplied with precursor gases from reservoirs 745 and 750. Reservoirs 735 and 745 each contain a first precursor gas. However, the precursor gas contained in reservoir 735 is at one concentration, while the same precursor gas is at a different concentration level in reservoir 745. Similarly, reservoirs 740 and 750 each contain a second precursor gas. Once again, the precursor gas contained in reservoir 740 is at one concentration, while the same precursor gas is at a different concentration level in reservoir 750. Thus, each zone 725 and 730 is supplied with a first and a second precursor gas, but each zone injects different concentration levels of these precursors. The variance in concentration from zone to zone may be used to compensate for fluctuation in concentration in regions of the reaction chamber that would otherwise occur.

To summarize, the inlet system 700 includes an inlet surface 710, which defines a plurality of inlets 720. The inlets 720 are organized into a plurality of zones 725, and 730. For each zone 725 and 730, there exists a reservoir for each precursor gas to be injected into the attached reaction chamber. As a consequence of this scheme, each zone 725 and 730 may inject precursor gases of differing concentrations. Of course, other variables may be made to vary from zone to zone, as well (for example, pressure, temperature, or ionic charge of the precursors may vary from zone to zone). Although the injection system 700 depicted in FIG. 10 contains two zones 725 and 730, each of which is supplied with two precursor gases, the injection system 700 may include any number of zones, each of which may be supplied with any number of precursor gases. All of the precursor gases supplied to a given zone may be at a single concentration level, or may be at varied concentration levels. That each precursor, zone by zone, can independently have its concentration varied is important to compensate for the variations in decomposition rates from one precursor to another. The inlets on downstream surface 710 of the injector 700 may include carrier inlets either in the form of discrete carrier inlets or a porous element as discussed above, and one or more sets of precursor inlets for one or more precursors.

FIG. 11 is an isometric depiction of an injector 800, which can be used in the spatially distributed injection system 700 of FIG. 10. As can be seen from FIG. 11, the downstream-facing (bottom) interior surface 810 of the injector 800 defines a plurality of inlets 820. The injector 800 also possesses a coolant inlet conduit 830 and coolant outlet conduit 835 for passing a cooling fluid (such as water) through a cooling chamber as discussed below. FIGS. 11-16 show a gas distribution injector with the downstream direction towards the top of the structure, i.e., with the reverse orientation from the injector of FIGS. 1-4. Inlets 820 are divided into three concentric zones 840, 850, and 860.

FIG. 12 depicts a cross-sectional isometric view of the injector 800 depicted in FIG. 11. Each of the inlets 820 is connected to one of two cylindrical chambers 900 and 910, which are defined by the body of the injector 800. The chamber 900 is divided into annular sub-chambers 920a, 920b and 920c, whereby chamber 910 is divided into annular sub-chambers 930a, 930b and 930c. Each zone 840, 850, and 860 is associated with one sub-chamber 920a-c of chamber 900 and with one subchamber 930a-c of chamber 910. For example, sub-chambers 920a and 930a correspond to zone 860. Accordingly, the inlets within zone 860 are connected to sub-chambers 920a and 930a. Similarly, the inlets within zone 850 are connected to sub-chambers 920b and 930b. The inlets within zone 840 are connected to sub-chambers 920c and 930c.

Sub-chambers 920a-c and 930a-c are referred to as subchambers, rather than as individual “chambers” because they result from sectioning a single chamber 900 or 910 into many “sub-chambers” via a plurality of walls. This aspect of the injector 800 is depicted in greater detail, below. As shown by FIG. 12, each of the sub-chambers 920a-c and 930a-c possesses an orifice connected to a conduit 940a-c and 950a-c respectively. The orifice and conduit combination permits injection of a precursor gas into subchambers 920a-c and 930a-c. Thus, each sub-chamber 920a-c and 930a-c may be supplied with its own source of precursor gas.

A cylindrical cooling chamber 960 is located between the reaction chamber (not depicted) and the first and second chambers 900 and 910. A coolant fluid, such as water, for example, is circulated through the cooling chamber 960. The inlets 820 pass through the cooling chamber 960 en route to the reaction chamber. Thus, the precursor gases pass through the cooling chamber 960 (without communicating therewith), and are thereby cooled to a temperature beneath the threshold point for the deposition reaction. A coolant such as water enters and exits the cooling chamber 960 to be recycled via water inlet 970 and water outlet 980.

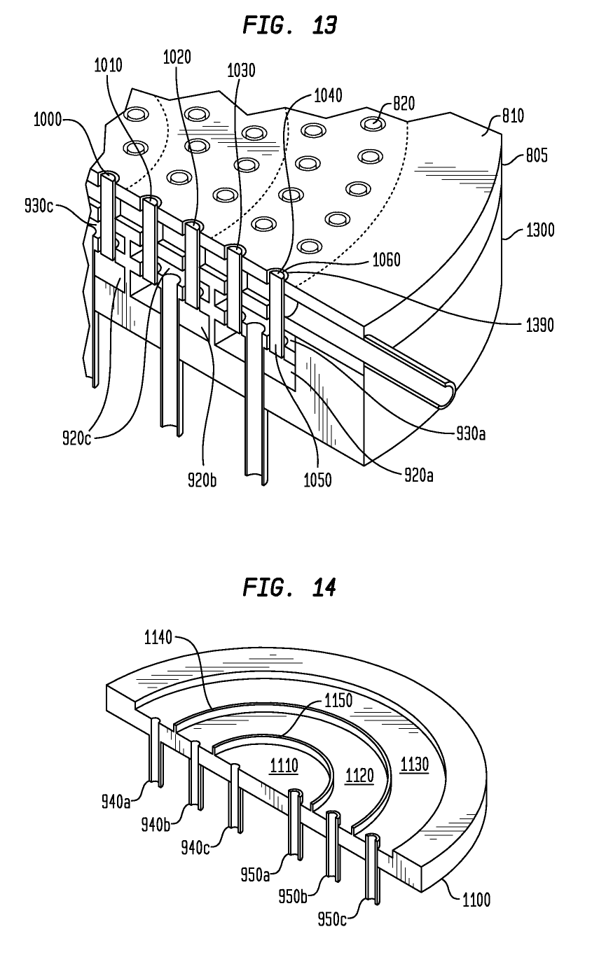

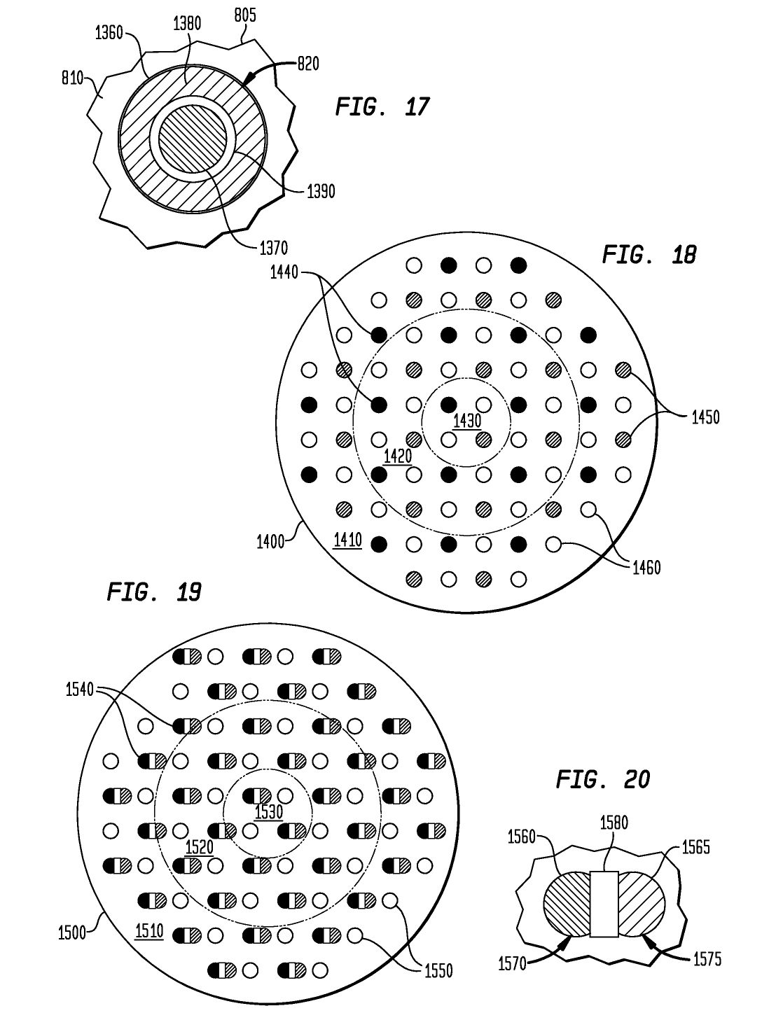

FIG. 13 depicts an enlarged view of a portion of the cross-section depicted in FIG. 12. As best seen in FIG. 13, each inlet 820 has a coaxial injection conduit, formed by a first conduit situated around a second conduit. For example, injection conduit 1040 includes an inner conduit 1050. The inner conduit 1050 provides a channel by which the precursor gas within subchamber 920a may travel to the reaction chamber. Around the inner conduit 1050 is an outer conduit 1060. The outer conduit 1060 provides a channel by which the precursor gas within sub-chamber 930a may travel to the reaction chamber. The inner and outer conduits 1050 and 1060 are preferably concentric. Thus, as shown in FIG. 17, at each inlet 820 in the downstream surface 810 includes the coaxial conduit including an inner conduit opening 1370 and an outer conduit opening 1380 divided by coaxial wall 1390. Coaxial conduit 1030 connects another inlet 820 to subchambers 930a and 920a, coaxial conduits 1020 and 1010 connect inlets to subchambers 930b and 920b, and coaxial conduit 1000 connects another inlet to subchambers 930c and 920c. Cross-sectional areas of the inner and outer conduits may be equal or unequal. The ratio of these areas may be varied from zone to zone or even within a zone. The coaxial conduit scheme permits the precursor gases to be transported from their respective subchambers to the reaction chamber without cross-communication between the precursors. Moreover, the concentric conduits can minimize deposit formation on surface 810. Although the two precursor gases exiting from each conduit mix with one another, it is believed that the outermost portion of the precursor gas stream exiting from outer conduit 1000 remains unmixed for a finite distance downstream from the inner downstream injector surface 810. Any reverse jetting or backflow towards surface 810 will be composed primarily of gas from this outermost portion.

The particular injector depicted in FIGS. 11-13 does not include provision for a separate inner carrier gas supply as discussed above. However, such an carrier gas supply, either with a porous element defining parts of surface 810 between outlets 820, or with discrete carrier gas outlets, may be provided, as discussed below, to further minimize reverse jetting. Use of coaxial conduits can simplify construction of the injector in that it can reduce the amount of sealing required. In addition, use of a coaxial scheme permits a more uniform distribution of the precursor material. Of course, the zoning arrangement of FIGS. 10-13 can be employed with separate first and second precursor inlets as shown in FIGS. 1-4. Particularly as shown in this alternative, the first precursor inlets are connected to sub-chambers 920a-920c while the second precursor gas inlets are connected to sub-chambers 930a-930c. Similarly, the coaxial conduits can be employed to disperse one or more precursor gases in an alternating or other pattern, as previously described herein, through the inner conduit, while dispersing a carrier gas through the outer conduit of each coaxial conduit.

FIGS. 14 through 16 are isometric cross-sectional views of a set of plates from which the injector 700 of FIG. 10 may be constructed.

In FIG. 14, an upstream plate 1100 is depicted. The upstream plate 1100 is preferably circular, and contains three recessed regions 1110, 1120 and 1130. Concentric circular walls 1140 and 1150 separate the recessed regions 1110, 1120 and 1130. Collectively, the recessed regions 1110, 1120 and 1130 make up the first chamber 900, shown in FIG. 12. Recessed region 1110 makes up sub-chamber 920c. Similarly, recessed regions 1120 and 1130 make up sub-chambers 920b and 920a, respectively. Based upon this understanding of FIG. 14, it can be seen that chamber 900 is generally cylindrical in shape, and is divided into a set of three concentric cylindrical sub-chambers 1110, 1120 and 1130. A first set of conduits 940a-c extend upstream (towards gas sources outside of the reactor) from recessed regions 1130, 1120 and 110, respectively. The conduits 940a, 940b and 940c serve as a channel by which precursor gases may be injected into the various sub-chambers formed by the recessed regions 1110, 1120 and 1130. A second set of conduits 950a, 950b and 950c extend through the upstream plate 1100. The second set of conduits project downstream (towards the reactor) from the upstream plate 1100 at a height approximately equal to that of the concentric circular walls 1140 and 1150. There may be more than one conduit per region, and the number of conduits may vary from one region to another.

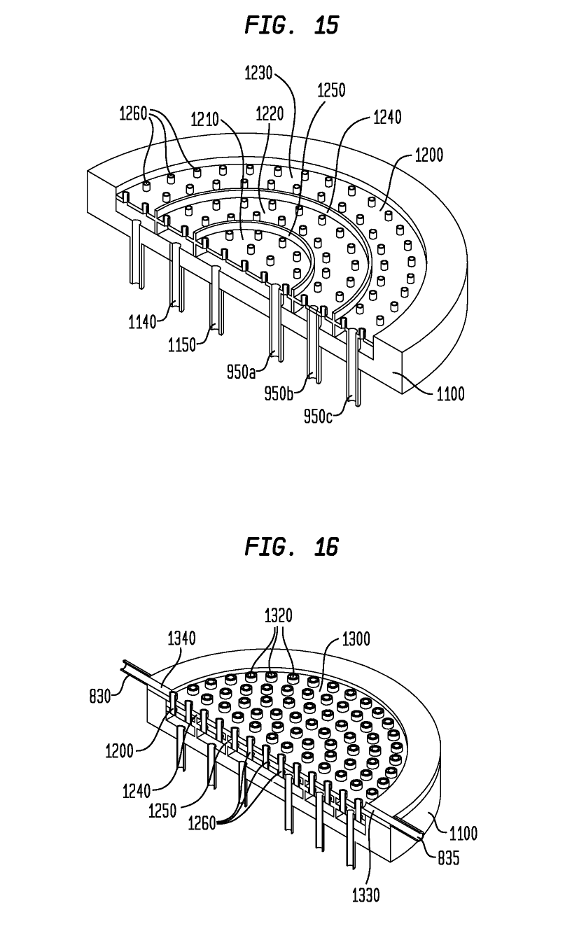

FIG. 15 depicts the middle plate 1200 stacked atop the upstream plate 1100. The middle plate 1200 rests atop the cylindrical walls 1140 and 1150 formed by the upstream plate 1100. Like the upstream plate 1100, the middle plate 1200 also contains recessed regions 1210, 1220 and 1230. The recessed regions 1210, 1220, and 1230 are separated by circular walls 1240 and 1250. The recessed regions 1210, 1220 and 1230 collectively make up the second chamber 910, and individually make up sub-chambers 930a, 930b and 930c, respectively. Informed by this understanding of FIG. 15, it can be seen that the first and second cylindrical chambers 900 and 910 are stacked atop each other, and share both a common face (middle plate 1200) and a common longitudinal axis. The middle plate 1200 joins each of the second set of conduits 950a, 950b and 950c, which protrude downstream (towards the reaction chamber) from the upstream plate 1100. Thus, the second set of conduits 950a, 950b, and 950c serve as channels by which precursor gases may be injected into the various sub-chambers formed by the recessed regions 1210, 1220, and 1230.

In addition, there may be multiple conduits per region, and the number of conduits may vary from one region to another. The middle plate 1200 also contains a plurality of injection conduits 1260, which project downstream (towards the reaction chamber) from the plate 1200, extending beyond the height of the circular walls 1240 and 1250. The full height of injection conduits 1260 is not shown in FIG. 16; portions of these conduits are removed for clarity of illustration.

FIG. 16 depicts the downstream plate 1300 stacked atop the middle plate 1200. The downstream plate 1300 rests atop the circular walls 1240 and 1250 formed by the middle plate 1200. The downstream plate forms the downstream portion of the cooling chamber 960, depicted in FIG. 12. Informed by this understanding of FIG. 16, it can be seen that the cylindrical cooling chamber 960 and the second cylindrical chamber 910 are stacked atop each other, share a common face (downstream plate 1300) and a common longitudinal axis.

As best seen in FIGS. 12 and 13, the cooling chamber 960 lies between the downstream plate 1300 and cover plate 805 which defines the interior or downstream facing surface 810 of the injector 1100. In this embodiment, conduits 1320 pass through the cooling chamber but do not communicate with the cooling chamber. As can be seen from FIG. 16, the side portion of the downstream plate 1300 provides entry and exit orifices 1330 and 1340 for the cooling chamber 960. The entry and exit orifices 1330 and 1340 join entry and exit conduits 830 and 835. Thus, the orifices 1330 and 1340 and the conduits 830 and 835 cooperate to the cooling chamber by which a coolant fluid may be circulated through the injector. The chamber for circulating the coolant may be an open chamber, as shown in FIG. 16, or may follow other two or three dimensional geometries, as shown by, for example, FIG. 5.

The downstream plate 1300 contains a plurality of injection conduits 1320, which project downstream towards the reaction chamber from the plate 1300, extending to the same height as the injection conduits 1260 joined by the middle plate 1200. The conduits 1320 joined to the downstream plate 1300 are formed around the conduits 1260 joined to the middle plate, thus creating the coaxial conduit structure described with reference to FIG. 13 and FIG. 17. As best shown in FIGS. 11, 12 and 13, a cover plate 805 overlies the downstream plate 1300 and defines the injection surface 810, depicted in FIG. 11 and defines the plurality of inlets 820, also depicted in FIG. 11. Further, the cover plate 805 seals the injector closed. At the inlets 820, the cover plate 805 is sealed to the injection conduits 1320. One embodiment of a coaxial inlet, shown in detail in FIG. 17, shows a coaxial inlet 820 on the injection (downstream) surface 810 of the cover plate 805. An outer coaxial inlet 1380 is defined by an outer coaxial wall 1360 and an inner coaxial wall 1390. The outer coaxial inlet 1380 partially or completely surrounds an inner coaxial inlet 1370 which is defined by the inner coaxial wall 1390. The outer coaxial inlet 1380 and inner coaxial inlet 1370 may distribute a first and second precursor gas, or, alternatively, the inner coaxial inlet 1370 may distribute a precursor gas while the outer coaxial inlet 1380 distributes a carrier gas shroud surrounding the precursor gas. The reverse, where carrier gas is carried by the inner coaxial inlet 1370, is also possible.

### III. Gas Distribution Injector with Zoned Inlets and Multi-Precursor Inlets (Coaxial or Dual Lumen)

FIG. 18 shows one embodiment of the present invention wherein multiple precursors are provided through inlets interspersed in a uniform field of carrier inlets. The downstream (interior) injector surface 1400 is divided into multiple zones 1410, 1420 and 1430. Within each zone, a checkerboard pattern of first precursor inlets 1440, second precursor inlets 1450, and carrier inlets 1460 are provided in order to evenly distribute precursors to a wafer carrier in a reactor without causing reverse jetting of material back onto the injector itself.

Similarly, in FIG. 19, a variation of the configuration of FIG. 18 is provided, wherein the first precursor inlets and second precursor inlets are combined into dual lumen inlets. Specifically, the downstream interior injector surface 1500 is divided into multiple zones 1510, 1520 and 1530. Within each zone, a checkerboard pattern of dual lumen precursor inlets 1540 and carrier inlets 1550 are provided in order to evenly distribute precursors to a wafer carrier in a reactor without causing reverse jetting of material back onto the injector itself.

As shown in FIG. 20, each dual lumen precursor inlet 1540 is divided into smaller conduits (inlets) 1560 and 1565 which carry a first precursor 1570 and a second precursor 1575, and which are divided by a lumen wall 1580 that separates the first precursor and second precursor until they enter the reactor chamber. The dual lumen inlets 1540 may be replaced by coaxial inlets 1590 as detailed in FIGS. 13-17 above. In the embodiments of either FIGS. 18-19, the carrier inlets may advantageously be replaced with a carrier porous plate as shown in FIG. 2.

FIGS. 21A-G provides a cross sectional view of some embodiments of the inlets of the present invention (excluding the carrier porous plate for clarity). As drawn, the inlets open downstream into the reaction chamber. FIG. 21A shows cross section 1600 including carrier inlets 1603 and precursor inlets 1606 interspersed in a simple checkerboard pattern. In FIG. 21B, cross section 1610 shows carrier inlets 1613 interspersed in a checkerboard pattern with dual lumen precursor inlets 1616 (of the type shown in FIG. 20), and cooling channel cross sections 1618. In FIG. 21C, cross section 1620 shows coaxial precursor inlets 1626 (of the type shown in FIG. 17) in a checkerboard pattern with carrier inlets 1623 with cooling channel cross sections 1628. In FIG. 21B, cross section 1610 shows the dual lumen precursor inlets 1616 include a linear barrier 1615 to seal the first precursor conduit from the second precursor conduit. Similarly, in FIG. 21C, the coaxial precursor inlets 1626 are in part defined by a radial barrier 1625 that seals the first precursor conduit from the surrounding second precursor conduit.

While FIGS. 21A-C showing cross sections 1600, 1610 and 1620 respectively each show approximately normal angles at the edges of the inlets, it is possible to possibly further reduce jetting by providing angled boundaries between the inlets and the interior downstream surface of the injector. Thus, in FIG. 21D cross section 1630 shows precursor inlets 1636 and carrier inlets 1633 interspersed in a simple checkerboard pattern, and beveled to further reduce jetting. In FIG. 21E cross section 1640 is similar to cross section 1630, except that in this example only the precursor inlets 1646 are beveled and carrier inlets 1643 remain normal. In FIG. 21F, cross section 1650 shows a dual lumen precursor inlets 1656 with linear barrier 1655 interspersed in a checkerboard pattern with carrier inlets 1653, where both the dual lumen inlet 1656 and carrier inlets 1653 are beveled at an approximately 45 degree angle to further minimize viscosity. Finally, in FIG. 21G, cross section 1660 shows coaxial precursor inlets 1666 with radial barrier 1665 in a checkerboard pattern with carrier inlets 1663. Cooling channel cross sections 1668 are not in gas communication with the coaxial precursor inlets 1666 or carrier inlets 1663 but are in thermal communication with inlets 1666 and 1663 in order to moderate the temperature of the injector during operation.

In FIGS. 21F and 21G, showing cross sections 1650 and 1660 respectively, the linear barrier 1655 and radial barrier 1665 are preferably beveled to end slightly before the boundary before the inlet and the reactor chamber to further minimize viscosity and jetting, although the barriers 1655 or 1665 may also end at or beyond the boundary depending on individual configurations for a particular injector.

### IV. Injector with Replaceable Inlet Elements Permitting Customizable Port and Orifice Size

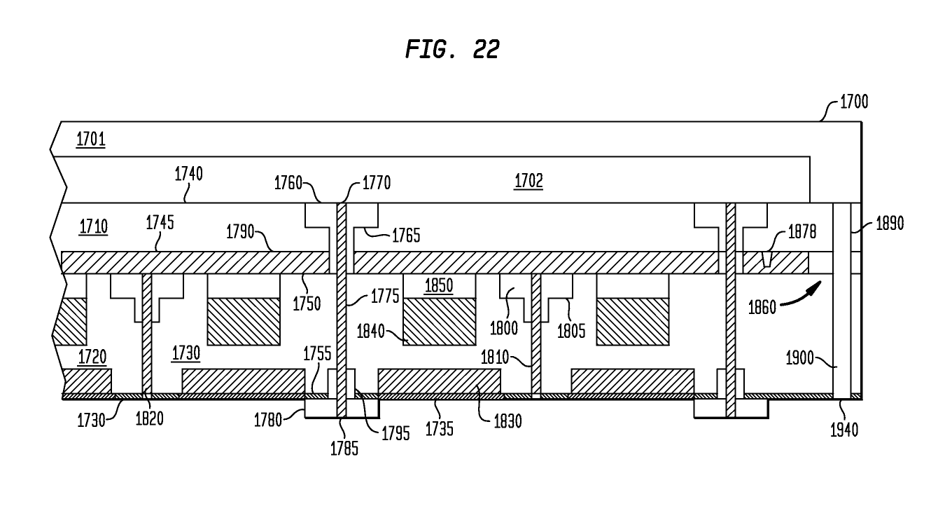

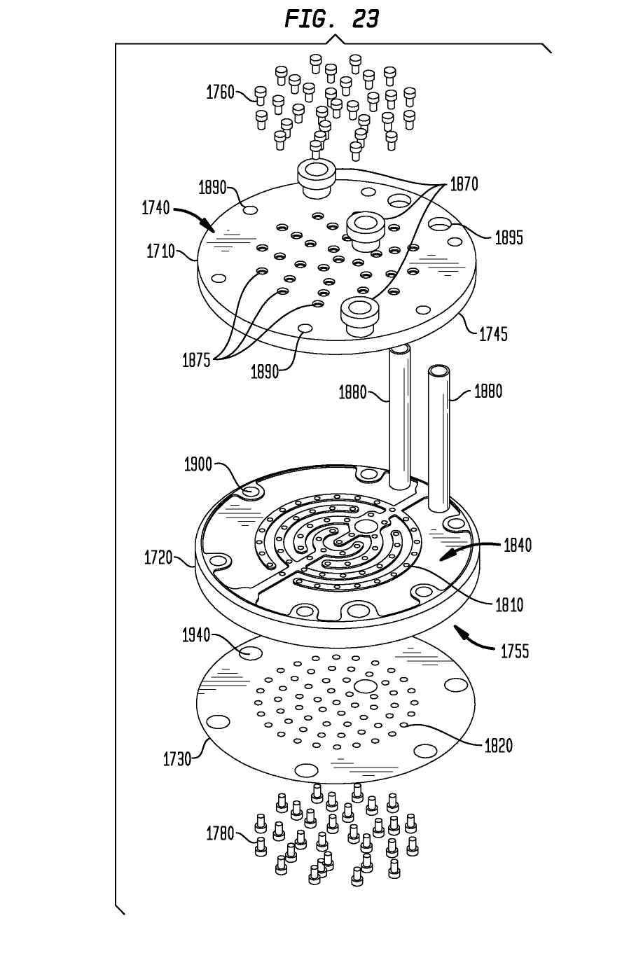

FIG. 22 is a simplified partial sectional view of another embodiment of a gas distribution injector of the present invention. The injector 1700 for placement in a deposition reactor is formed from an upstream plate 1710, a middle plate 1720, and a downstream plate 1730 which are joined together via a sealing process such as, for example, vacuum brazing, welding, or a bolt-and-seal arrangement. The injector is typically coupled to a sealing plate 1701 of the reaction chamber (see FIG. 2). FIG. 23 is an exploded view of an embodiment of a gas distribution injector of the present invention employing multiple gas distribution plates and including vent screws used for communication of gasses to the reaction chamber. The gas distribution injector is, for example, located below a reactor sealing plate (not shown) with which it forms a first reactant gas manifold (see FIG. 2), and is preferably located within a reaction chamber (not shown, see FIG. 1) such that a wafer carrier (not shown, see FIG. 1) is centrally located below the gas distribution injector.

As shown in FIG. 22, upstream plate 1710 includes an upstream surface 1740 and a downstream surface 1745. A space defining a first reactant gas manifold 1702 is typically located between the upstream surface 1740 of the upstream plate 1710 and the sealing plate 1701 (See, e.g., FIG. 2, 270a-c). Preferably flush with the upstream surface 1740 of the upstream plate 1710 are one or more gas inlet elements, in this case vent screws 1760, with a gas inlet 1770 centrally located within each vent screw 1760. The vent screws 1760 are secured to the upstream surface 1740 of the upstream plate 1710 via one or more screw holes 1765 in the upstream surface 1740 of the upstream plate 1710, where the screw holes 1765 are aligned to the first reactant gas passage.

In FIG. 23, the upstream plate 1710, middle plate 1720 and downstream plate 1730 described in FIG. 22 are seen in perspective. In the upstream plate 1710 as shown in FIG. 23, a plurality of vent screws 1760 are secured in the vent screw holes 1875 to provide an inlet for a first reactant gas from the first gas manifold into the gas distribution injector. Injector sealing ports 1870, for optical ports or communication of gas sources to within the gas distribution injector, are located on the top surface 1740. Coolant pass-through openings 1895 permit coolant entry and exit lines to pass through the structure of the upstream plate 1710. Finally, bolt holes 1890 permit sealing of the upstream plates to the other injector plates and to the sealing plate of the reactor.

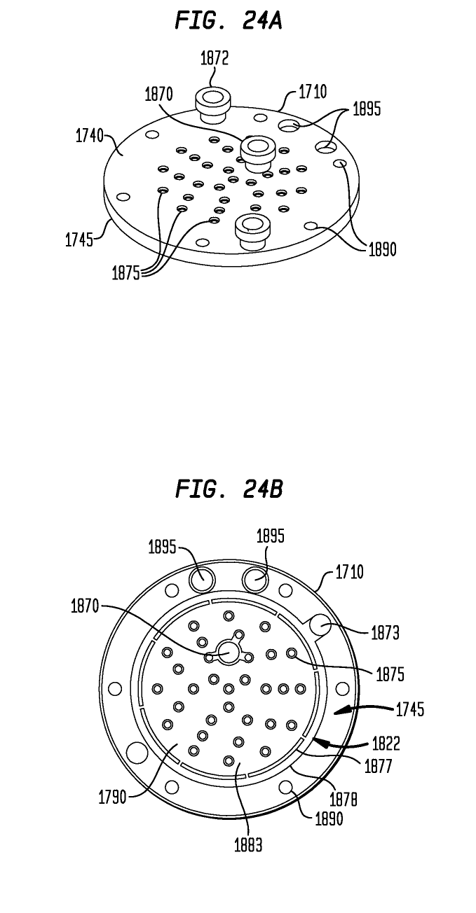

FIG. 24A is a perspective view in more detail of the upstream plate of the embodiment of the gas distribution injector shown in FIG. 22. The upstream plate 1710 is shown with its top surface 1740 visible and a plurality of vent screw holes 1875 visible therein. In addition, a set of coolant pass-through openings 1895 permit entry and exit of coolant conduits through the upstream plate to the middle plate (not shown) where cooling channels are located. A plurality of sealing ports 1870 are provided for communication of gasses and/or optical ports to within or through the gas distribution injector. In particular, a second reaction gas sealing port 1872 is provided for communicating a second reaction gas through the upstream plate 1710 to the region between the downstream surface 1745 of the upstream plate and the upstream surface of the middle plate (not shown) that define a second reactant gas manifold 1790.

FIG. 24B is a bottom-up view of the upstream plate of the embodiment of the gas distribution injector shown in FIG. 22, showing the downstream surface 1745 of the upstream plate 1710 in more detail. As described previously, the upstream plate 1710 includes a plurality of coolant pass-through openings 1895, gas vent screw holes 1875 for passing first reaction gas passages through, pass throughs for sealing ports 1870, and bolt holes 1890 for coupling the upstream, middle and downstream plates together.

The second reaction gas sealing port includes a second reaction gas sealing port outlet 1873 which communicates a second reaction gas to the body of the second reaction gas manifold 1790. Optionally within the second reaction gas manifold 1790, a radial barrier 1878 defines two regions of the second reaction gas manifold 1790: an outer ring 1878 into which the second reaction gas is initially communicated by the second reaction gas sealing port outlet 1873, and an inner manifold region 1883 in which the second reaction gas is communicated into the middle plate 1720 as described herein. The outer ring 1878 and inner manifold region 1883 communicate via a plurality of orifices 1882, which serve to equalize the gas pressure of the second reaction gas within the inner manifold region 1883 of the second reaction gas manifold 1790.

Returning to FIG. 22, the middle plate 1720 includes an upstream surface 1750 and a downstream surface 1755. The upstream plate 1710 and middle plate 1720 may be coupled together by, for example, vacuum welding or bolt-and-seal arrangements at a point of contact 1860 between the upstream plate 1710 and middle plate 1720. A portion of the downstream surface 1745 of the upstream plate 1710, along with the upstream surface 1750 of the middle plate 1720, form a second reactant gas manifold 1790 for introduction of a second reactant gas into the reaction chamber. A gas inlet 1810 (optionally via one or more vent screws 1800 secured in or more vent screw holes 1805 are made in the upstream surface 1750 of the middle plate 1720).

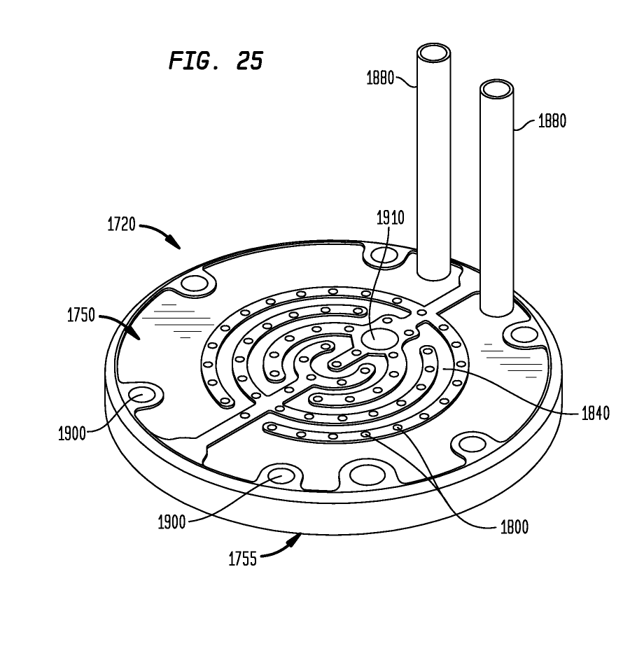

Formed into the upstream surface 1750 of the middle plate 1720 is a cooling channel 1840 (see, e.g., FIGS. 5 and 25A-C). The upstream end of the cooling channel 1840 is sealed and separated from the other components of the gas distribution injector 1700, and in particular is sealed from the upstream surface 1750 of the middle plate 1720, via a cooling channel cover piece 1850 preferably vacuum welded to the upstream surface 1750 of the middle plate 1720 to form a contiguous surface on the upstream surface 1750 of the middle plate 1720 and thus forming a contiguous water cooling channel 1840 as described in more detail in FIGS. 25A-C.

Formed in the downstream surface 1755 of the middle plate 1720 are one or more carrier gas manifolds 1830 which receive a preferably non-reactive carrier gas for distribution into the reactor. Also formed in the downstream surface 1755 of the middle plate 1720 are vent screw holes 1795 for securing first gas outlet vent screws 1780 including a first gas outlet 1785 therein. The first gas outlet vent screws 1780 and first gas outlet 1785 serve as a terminus for the first gas passage 1775, thus permitting first reactant gas to be transmitted from the first gas manifold to the reaction chamber there through. Further formed in the downstream surface 1755 of the middle plate 1720 is a second gas outlet 1820 which serves as a terminus for the second gas passage 1815, thus permitting a second reactant gas to be transmitted from the second gas manifold 1790 to the reaction chamber there through. Alternatively, the second gas outlet 1820 may be formed from a vent screw configuration similar to that used for the first gas outlet 1785.

As shown in an exploded view in FIG. 23 and described from a different visual perspective, the middle plate 1720 includes a welded upstream surface sheet 1840 and a downstream surface 1755, and is coupled to coolant inlet and outlet pipes 1880 which provide a coolant, such as water, to the cooling channel located within the middle plate 1720 as described herein. Gas inlets 1810 are located in the upstream surface sheet 1840 of the middle plate 1720, some of which are coupled to the first gas inlets in the upstream plate 1720, and some of which directly receive a second gas from a second gas manifold formed between the downstream surface of the upstream plate 1745 and the upstream surface 1840 of the middle plate 1720. Bolt holes 1900 permit the sealing of the middle plate to the other plates of the injector.

FIG. 25 is a perspective view in more detail of the middle plate of the embodiment of the gas distribution injector shown in FIG. 22. The upstream surface 1750 of the middle plate 1720 serves to define the downstream end of the second gas distribution manifold 1790, including gas inlets 1800 for the second reactant gas (and for the first gas passages that pass through but do not communicate with the second gas distribution manifold). The middle plate 1720 also includes the cooling channel 1840 for the gas distribution injector. The middle plate further includes bolt holes 1900 for securing the upstream, middle and downstream plates together, and sealing port line pass throughs 1910 for optical viewports or communication of gasses within the gas distribution system.

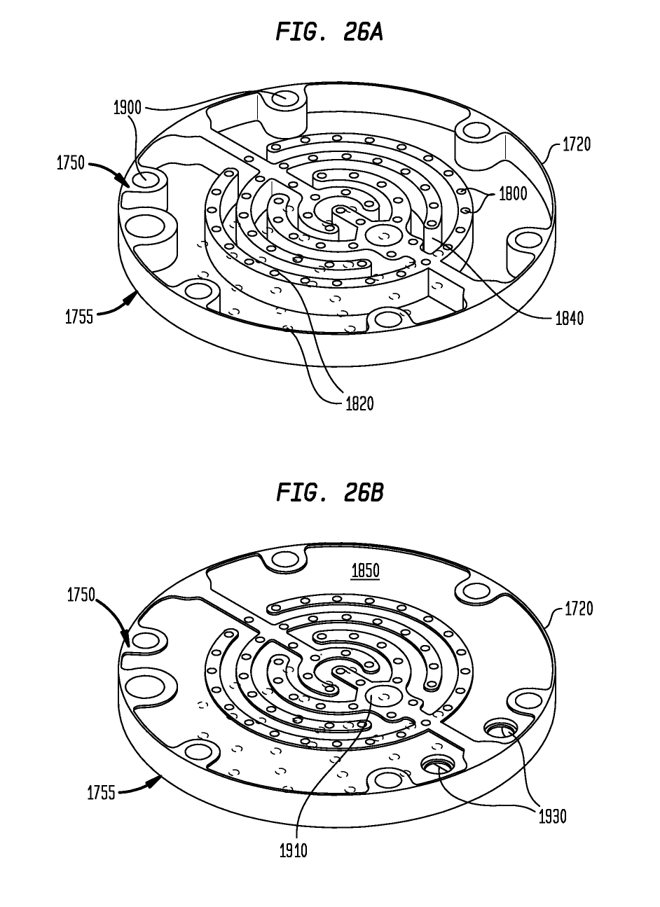

FIG. 26A is a perspective view of the middle plate of the embodiment of the gas distribution injector shown in FIG. 22, prior to welding of the cooling channel cover piece 1850 (see FIG. 26B) on the upstream surface thereon, to more clearly show the cooling channel 1840 located therein. Reactant gas inlets 1820 on the upstream surface 1750 of the middle plate 1720 are shown in solid lines, and the outlets of the reactant gas inlets 1820 on the downstream surface 1755 are shown in dashed outline. FIG. 26B is a perspective view of the middle plate of the embodiment of the gas distribution injector shown in FIG. 22, after welding of the cooling channel cover piece 1850 on the upstream surface thereon. Coolant conduits 1930 provide for entry and exit of a coolant, such as water, into the cooling channel 1840 shown in FIG. 26A.

Returning again to FIG. 22, the downstream plate 1730 may be a thin sheet including a single or a plurality of permeable or perforated region(s) 1735 arranged therein. The downstream plate 1730 is coupled to the downstream surface 1755 of the middle plate 1720 via a process such as, for example, vacuum welding or a bolt-and-seal arrangement. The perforated regions 1735 of the downstream plate 1730 at least coincide with the carrier gas manifolds 1830 in the downstream surface 1755 of the middle plate 1720 so as to permit distribution of the carrier gas into the reaction chamber located downstream of the downstream plate 1730.

At the downstream plate 1730, first reactant gas passages 1775 terminate with a gas outlet 1785 located on the downstream plate 1730, alone or within a removable device such as a gas outlet vent screw 1780. Optionally, gas outlet vent screws 1780 may be advantageously secured to the downstream plate 1730 so as to secure the downstream plate 1730 between the gas outlet vent screw 1780 and the downstream surface 1755 of the middle plate 1720. The second reactant gas outlet 1820, through which the second gas passage 1815 terminates, preferably communicates entirely through the downstream plate 1730 so as to distribute a second reactant gas to the reaction chamber.

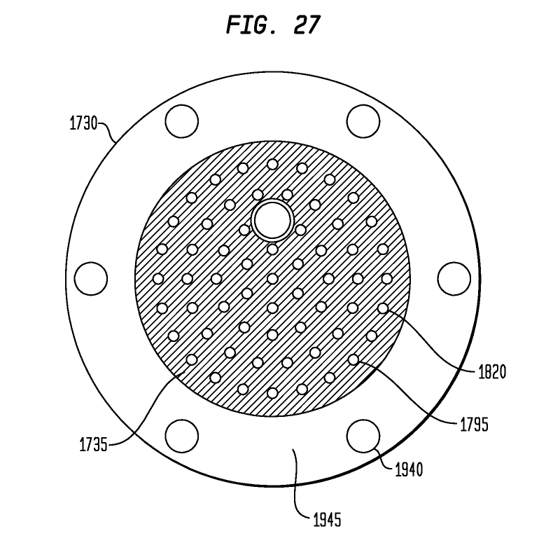

As shown from another perspective in FIG. 23, the downstream plate 1730 includes a plurality of holes 1820 through which first gas outlets and second gas outlets from the downstream surface 1755 of the middle plate 1720 can communicate with the reaction chamber. Finally, a plurality of gas outlet vent screws 1780 are secured to outlet vent screw holes (see FIG. 22) in the bottom 1755 of the middle plate 1720 so as to further secure the downstream plate 1730 between the gas outlet vent screws 1780 and the middle plate 1720. The gas outlet vent screws are employed for first reactant gas outlets as shown in FIG. 22, but optionally may be employed for second reactant gas outlets as well. Finally, bolt holes 1940 in the downstream plate are advantageously aligned with the bolt holes 1900 of the middle plate and the bolt holes 1890 of the upstream plate for bolting together and sealing, or otherwise connecting, the upstream, middle and downstream plate. On the downstream plate, as seen in FIG. 27, is preferably a carrier gas screen for dispersing carrier gas in the region between the reaction gas outlets.

FIG. 27 is a view of the downstream plate of the embodiment of the gas distribution injector shown in FIG. 22, from the inside of the reactor (from the downstream direction). The downstream plate 1730 includes a carrier gas screen 1735 that is porous or permeable to a carrier gas that is passed there through. The carrier gas screen 1735 is shown as a single continuous region, but it may also be provided, for example, in a discrete plurality of regions located vertically adjacent to carrier gas manifolds 1830, as discrete gas inlets, as a plurality of outer coaxial inlets for each of a plurality of coaxial inner reactant inlets, or in other configurations. Orifices are provided for first gas vent holes 1795 and second gas outlets 1820 through the downstream plate 1730. An outer region 1945 of the downstream plate 1730 is preferably solid and does not constitute a screen. Bolt holes 1940 are provided for securing the upstream, middle and downstream plates to one another and to the reactor.

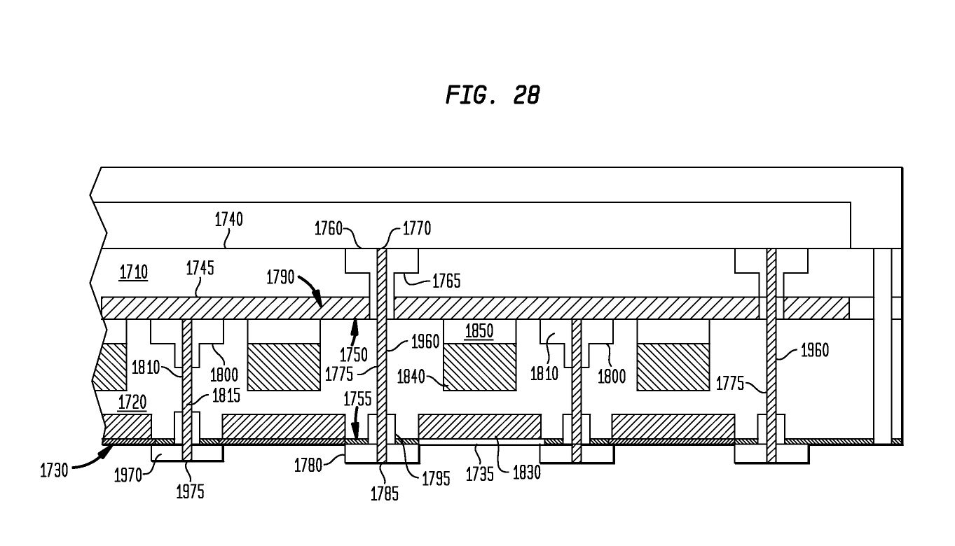

FIG. 28 is a cross-sectional view of one embodiment of a gas distribution injector of the present invention including a porous material placed within the reactant gas inlet passages to create a pressure differential. Otherwise similar to the embodiment of FIG. 22, FIG. 28 further shows the introduction into the first gas passage 1775 of a permeable material 1960 for controlling gas pressure and the use of second gas outlet vent screws 1970 for the second gas outlet 1975 just as with the first gas outlet vent screws 1780 previously described.

The permeable material 1960, which may, for example, be a carbon filter or another permeable material that is not reactive with the first reaction gas passed there through, serves to create a pressure differential between the first gas inlet 1770 and the first gas outlet 1785. Alternatively, a permeable material may also be used with the second gas passage.

In addition, in place of or in addition to a permeable material, the internal diameter of the vent screws 1760 and 1785 or other removable gas inlet devices may be respectively altered to create a similar pressure differential, by, for example, increasing or decreasing the size of the aperture of the first gas inlet 1770 in the first gas inlet vent screw 1760 and/or increasing or decreasing the size of the gas outlet 1785 in the first gas outlet vent screw 1780.

Also, gas outlet vent screws have been employed in FIG. 28 for distribution of both the first reactant gas and the second reactant gas. In particular, the second gas outlet vent screws 1970 are provided for the second gas outlet 1975 just as the first gas outlet vent screws 1780 previously described are provided for the first gas outlet 1785. By altering the configuration of the vent screws, including the depth of the vent screw, how far the head of the vent screw exceeds the surface of the downstream plate, or the diameter of the gas inlets and gas outlets centrally located within the respective vent screws, gas outlet orifice sizes in the vent screw and dimensions can thus be advantageously customized based on reactor and gas injector configuration without the need to replace the other structural components of the gas injector.

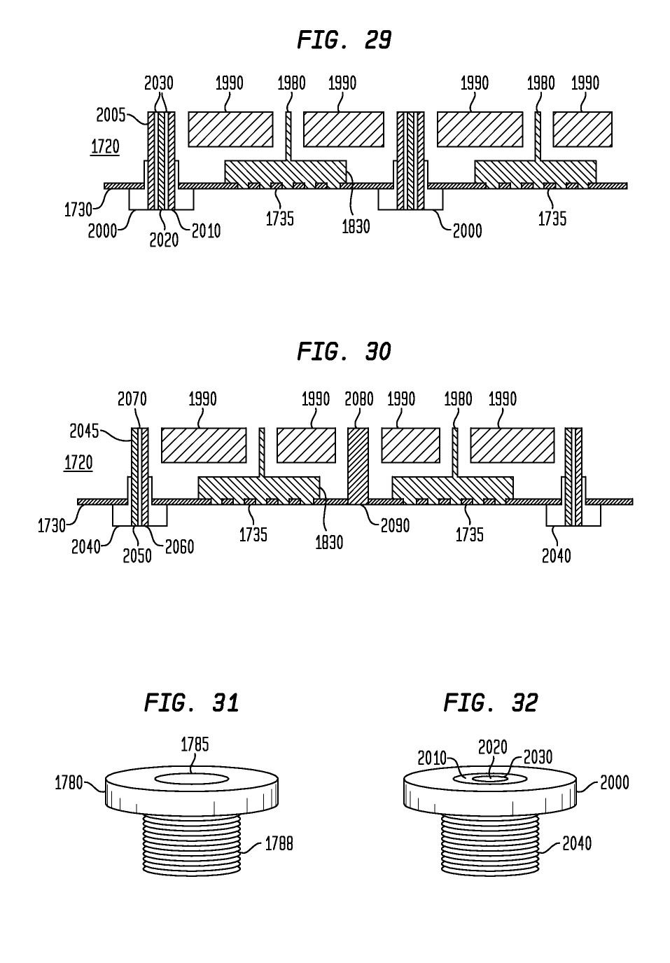

FIG. 29 is a cross sectional view of the inner gas distribution surface of one embodiment of a gas distribution injector of the present invention employing a coaxial reactant gas inlet and vent screw. A coaxial gas outlet vent screw 2000 is coupled to the downstream plate 1730 and to a coaxial reaction gas passage 2005 in the middle plate 1720. The coaxial reaction gas passage 2005 includes an outer passage 2010 for a first gas and an inner passage 2020 for a second gas, where the inner and outer passages are separated by an inner radial wall 2030. As previously described, the middle plate 1720 includes a carrier gas manifold 1830, which receives carrier gas from a carrier gas passage 1980, and which distributes gas out of the gas distribution injector via a porous screen 1735 in the downstream plate 1730. A cross section of the cooling channel 1990 in the middle plate 1720 is also shown.

FIG. 30 is a cross sectional view of the inner gas distribution surface of one embodiment of a gas distribution injector of the present invention employing a non-coaxial dual lumen reactant gas inlet and vent screw and a supplemental reactant gas inlet. A dual lumen gas outlet vent screw 2040 is coupled to the downstream plate 1730 and to a dual lumen reaction gas passage 2045 in the middle plate 1720. The dual lumen reaction gas passage 2045 includes a left passage 2050 for a first gas and a right passage 2060 for a second gas, where the right and left passages are separated by a central wall 2070. As evidenced by the supplemental reaction gas outlet 2090 is shown connected to a supplemental reaction gas passage 2080 that does not use a coaxial, dual lumen, or vent screw design, the various inlet and outlet designs described herein, including those shown in FIGS. 21A-G, and vent screws of different gauges, inlet diameters, and outlet shapes, can be combined in the same gas distribution injector to permit a large variety of gas distribution configurations. In place of the carrier screen 1735, for example, a first and second coaxial inlet can be provided for distributing a first and second precursor gas, where the first and second precursors are distributed via the inside coaxial channel of each coaxial inlet, and a carrier gas is distributed via the outside coaxial channel of each coaxial inlet.

FIG. 31 is a perspective view of a vent screw to be used in one embodiment of the gas distribution injector of the present invention. A single passage vent screw 1780 is includes threads 1788 for securing the vent screw 1780 in one of the plates of the gas distribution injector. A central gas outlet 1785 extends through the body of the vent screw 1780 so as to permit the gas to vent completely through the screw when the vent screw 1780 is secured to the end of a gas outlet in a plate of the gas distribution system. FIG. 32 is a perspective view of a coaxial vent screw to be used in one embodiment of the gas distribution injector of the present invention employing coaxial distribution of reactant gases. The screw includes a central radial wall 2030 that may extend partially or completely through the length of the vent screw, where arms couple the inner wall to the remainder of the body of the screw. The central radial wall 2030 separates an outer gas outlet 2010 from an inner gas outlet 2020, that is advantageously coupled to a coaxial gas passage in the plate to which the vent screw is secured via, for example, threads 2040.

It will be clear that the present invention is well adapted to attain the ends and advantages mentioned as well as those inherent therein. While presently preferred embodiments have been described for purposes of this disclosure, it is to be understood that these embodiments are merely illustrative of the principles and applications of the present invention and various changes and modifications may be made which are well within the scope of the present invention. For example, the deposition system may be of any shape, and may be divided into any number of zones, which, themselves, may be of any shape. Additionally, variables other than precursor concentration may be controlled from zone to zone. For example, precursor pressure or local plasma augmentation may be controlled from zone to zone. Numerous other changes may be made which will readily suggest themselves to those skilled in the art and which are encompassed in the spirit and scope of the invention disclosed and as defined by the appended claims.

1. An injector for a chemical vapor deposition reactor, the injector defining an interior surface facing in a downstream direction and having a horizontal extent, the injector comprising:
a plurality of unitary plate members arranged in a stacked relationship along an axis extending generally in an upstream to downstream direction, such that a downstream side of one of the plate members confronts an upstream side of another one of the plate members and the confronting plate members define a first chamber between them, a first one of the unitary plate members having a plurality of first projections integral with that plate member and extending into the first chamber towards a second one of the plate members so that the first projections of the first plate member sealingly engage the second plate member, the first and second plate members defining first gas passages extending in the upstream to downstream direction through the first projections and through the first and second plate members but not communicating with the first chamber, each of the first gas passages having a downstream end communicating with one of a plurality of first gas inlets open to the interior surface.

2. The injector of claim 1, wherein one of the unitary plate members has a plurality of second projections integral with that plate member and extending into a second chamber, a plurality of second gas passages being defined through the second projections in the upstream to downstream direction, each of the second gas passages having a downstream end communicating with one of a plurality of second gas inlets open to the interior surface.

3. The injector of claim 2, wherein each of the first gas passages has an upstream end communicating with the second chamber.

4. The injector of claim 2, wherein each of the second gas passages has an upstream end communicating with a third chamber.

5. The injector of claim 2, wherein at least some of the first and second gas inlets are interspersed with one another over at least a portion of the horizontal extent of the interior surface.

6. The injector of claim 2, wherein each of the first gas passages surrounds and is substantially coaxial to one of the plurality of second gas passages, and wherein each of the first gas inlets surrounds one of the plurality of second gas inlets.

7. The injector of claim 1, wherein the plurality of projections includes a plurality of elongated, horizontally extensive walls cooperatively defining a serpentine passageway within the first chamber.

8. The injector of claim 1, wherein the first chamber is at least partially bounded by a porous structure defined by openings distinct from the first gas inlets, the openings being substantially smaller than the first gas inlets and spaced-apart substantially closer together than the first gas inlets, and wherein the porous structure defines at least a portion of the interior surface between at least some of the first gas inlets.

9. The injector of claim 1, wherein the first chamber is divided into a plurality of concentric sub-chambers, each of the sub-chambers including a separate gas connection for supplying gas thereto.

10. The injector of claim 1, wherein plate members are connected to each other by one or more vacuum tight connections selected from the group consisting of: vacuum brazing, diffusion welding, and bolt-and-seal.

11. A chemical vapor deposition reactor, comprising:
a reaction chamber;
an injector as recited in claim 1 for introducing a plurality of gases into the reaction chamber, the injector being disposed at an upstream end of the reaction chamber; and
a substrate carrier mounted in the reaction chamber downstream from the injector, the carrier being rotatable about an axis extending in the downstream direction.

12. A gas distribution system for a chemical vapor deposition reactor, comprising:
an injector as recited in claim 1; and
a cooling fluid source connected to the first chamber for supplying a cooling fluid through the first chamber.

13. A gas distribution system for a chemical vapor deposition reactor, comprising:
an injector as recited in claim 1; and
a first gas source in fluid communication with the first gas passages for supplying a first precursor gas through the first gas inlets.

14. The gas distribution system of claim 13, wherein the first chamber is at least partially bounded by a porous structure, the porous structure defined by openings distinct from the first gas inlets, the openings being substantially smaller than the first gas inlets and spaced-apart substantially closer together than the first gas inlets, wherein the porous structure defines at least a portion of the interior surface between at least some of the first gas inlets, and wherein the first chamber is connected to a source of carrier gas for supplying the carrier gas through the porous structure, the carrier gas being substantially nonreactive with the first precursor gas.

15. A gas distribution system for a chemical vapor deposition reactor, comprising:
an injector as recited in claim 2;
a first gas source in fluid communication with the first gas passages for supplying a first precursor gas through the first gas inlets; and
a second gas source in fluid communication with the second gas passages for supplying a second precursor gas through the second gas inlets, the second precursor gas being reactive with the first precursor gas.

16. A gas distribution system for a chemical vapor deposition reactor, comprising:
an injector as recited in claim 6; and
a first gas source in fluid communication with the first gas passages for supplying a first gas through the first gas inlets;
a second gas source in fluid communication with the second gas passages for supplying a second gas through the second gas inlets.

17. The gas distribution system of claim 16, wherein the first gas is a precursor gas and the second gas is a carrier gas, the precursor gas being reactive so as to form a reaction deposit on one or more substrates, and the carrier gas being substantially nonreactive with the precursor gas.

18. The gas distribution system of claim 16, wherein the second gas is a precursor gas and the first gas is a carrier gas, the precursor gas being reactive so as to form a reaction deposit on one or more substrates, and the carrier gas being substantially nonreactive with the precursor gas.

19. The gas distribution system of claim 16, wherein the first gas is a first precursor gas and the second gas is a second precursor gas, the second precursor gas being reactive with the first precursor gas.
